(19) United States
(12) Patent Application Publication
(10) Pub. No.: US 2025/0379151 A1
(43) Pub. Date: Dec. 11, 2025

(54) SEMICONDUCTOR DEVICES AND METHODS FOR FORMING THE SAME

(71) Applicant: Yangtze Memory Technologies Co., Ltd., Wuhan (CN)

(72) Inventors: Wei YUAN, Wuhan (CN); Yuhui HAN, Wuhan (CN); Kun ZHANG, Wuhan (CN); Huiwen LIU, Wuhan (CN); Zhenyu LIU, Wuhan (CN); Xiaojing GU, Wuhan (CN)

(21) Appl. No.: 18/790,769

(22) Filed: Jul. 31, 2024

Related U.S. Application Data
(63) Continuation of application No. PCT/CN2024/097441, filed on Jun. 5, 2024.

(51) Int. Cl. H01L 23/532; H01L 23/528; H10B 43/10; H10B 43/27; H10B 43/35; H10B 43/40

(52) U.S. Cl. CPC H01L 23/53295; H01L 23/5283; H10B 43/10; H10B 43/27; H10B 43/35; H10B 43/40

(57) ABSTRACT

The present disclosure relates to methods, devices, systems, and techniques for gate line structures in semiconductor devices. An example semiconductor device includes a semiconductor structure including a stack of alternating conductive layers and isolating layers. The semiconductor device further includes channel structures extending through the stack along a first direction. The channel structures include at least a first channel structure that has a top end and a bottom end along the first direction. The first channel structure includes a channel plug at the top end. The semiconductor device further includes a gate line structure extending through the stack along the first direction. The gate line structure includes a top portion and a body portion arranged along the first direction. The top portion of the gate line structure is farther away from the bottom end of the first channel structure than the channel plug along the first direction.

### CROSS-REFERENCE TO RELATED APPLICATIONS

This application is a continuation of International Application No. PCT/CN2024/097441, filed on Jun. 5, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques related to gate line structures in semiconductor devices.

One aspect of the present disclosure features a semiconductor device. The semiconductor device includes a semiconductor structure including a stack of conductive layers and isolating layers alternating with each other along a first direction. The semiconductor device further includes channel structures extending through the stack along the first direction. The channel structures include at least a first channel structure that has a top end and a bottom end along the first direction. The first channel structure includes a channel plug at the top end. The semiconductor device further includes a gate line structure extending through the stack along the first direction. The gate line structure includes a top portion and a body portion arranged along the first direction. The top portion of the gate line structure is farther away from the bottom end of the first channel structure than the channel plug along the first direction.

In some implementations, the semiconductor structure includes an array region and a connection region adjacent to the array region in a second direction perpendicular to the first direction.

In some implementations, a side surface of the top portion includes a curved surface and a flat surface. The flat surface is between the curved surface and the body portion along the first direction. A side surface of the body portion includes a series of curved surfaces arranged along a second direction perpendicular to the first direction.

In some implementations, the side surface of the body portion includes wavy patterns repeating along the second direction.

In some implementations, the side surface of the top portion has a uniform profile along the second direction, and the flat surface of the side surface of the top portion is a smooth surface absent of lumps or indentations.

In some implementations, a first cross section of the top portion and a second cross section of the top portion are in contact with the curved surface and are perpendicular to the first direction, and the first cross section of the top portion is farther away from the body portion than the second cross section along the first direction. A size of the first cross section along a third direction perpendicular to the first direction and the second direction is larger than a size of the second cross section along the third direction.

In some implementations, the top portion includes a first portion and a second portion arranged along the first direction. The second portion is connected to the body portion. The first portion is farther away from the body portion than the second portion along the first direction. A size of the first portion along a third direction perpendicular to the first direction and the second direction is larger than or equal to a size of the second portion along the third direction.

In some implementations, a third cross section of the top portion is in contact with the flat surface and is perpendicular to the first direction, and a size of the third cross section along the third direction is smaller than a size of a cross section of the body portion along the third direction.

In some implementations, the size of the second portion of the top portion along the third direction is smaller than a size of the body portion along the third direction.

In some implementations, the top portion of the gate line structure extends beyond the channel plug along the first direction by a length in a range between 20 nanometers (nm) and 300 nm.

In some implementations, the gate line structure includes an outer layer and an inner layer surrounded by the outer layer, the outer layer includes a dielectric material, and the inner layer includes a semiconductor material.

In some implementations, the semiconductor structure includes a semiconductor layer connected to the body portion of the gate line structure and the bottom end of the first channel structure.

In some implementations, the semiconductor structure is a first semiconductor structure, the semiconductor device further includes a second semiconductor structure including a peripheral circuit configured to control the channel structures, and the first semiconductor structure is connected to the second semiconductor structure along the first direction.

In some implementations, the semiconductor device further includes a substrate and a peripheral circuit. The peripheral circuit is configured to control the channel structures. The peripheral circuit is between the stack and the substrate along the first direction. The peripheral circuit is connected to the body portion of the gate line structure and the bottom end of the first channel structure.

Another aspect of the present disclosure features a method including forming a semiconductor structure that includes a stack of sacrificial layers and isolating layers alternating with each other along a first direction. The method further includes forming channel structures extending through the stack along the first direction. The channel structures include at least a first channel structure that has a top end and a bottom end along the first direction. The first channel structure includes a channel plug at the top end. The method further includes forming a gate line structure. The gate line structure includes a top portion and a body portion arranged along the first direction. The top portion of the gate line structure is farther away from the bottom end of the first channel structure than the channel plug along the first direction.

In some implementations, the method further includes depositing a dielectric layer on top of the stack to cover the channel structures and gate line holes. The gate line holes are spaced from one another along a second direction perpendicular to the first direction and are filled with a filler material. The method further includes forming a trench in the dielectric layer to expose the filler material of the gate line holes; removing the filler material from the gate line holes; and forming a gate line space by expanding the trench and the gate line holes, where the expanded gate line holes are connected.

In some implementations, the gate line space includes a top portion formed by the expanded trench and a body portion formed by the expanded gate line holes. A first cross section of the top portion and a second cross section of the top portion are perpendicular to the first direction. The first cross section of the top portion is farther away from the body portion than the second cross section along the first direction. A size of the first cross section along a third direction perpendicular to the first direction and the second direction is larger than a size of the second cross section along the third direction.

In some implementations, a third cross section of the top portion is adjacent to the body portion and perpendicular to the first direction, and a size of the third cross section along the third direction is smaller than a size of the body portion along the third direction.

In some implementations, the method further includes forming the gate line holes and channel holes extending through the stack along the first direction. The gate line holes include gate line holes in an array region of the semiconductor structure and gate line holes in a connection region of the semiconductor structure. The channel structures are formed in the channel holes.

In some implementations, the method further includes forming the channel structures in the channel holes prior to forming the gate line space by expanding the trench and the gate line holes. The channel structures are formed by depositing a high-K layer, a block layer, a charge trapping layer, a tunneling layer, a channel layer, and a core filler layer into each of the channel holes.

In some implementations, forming the semiconductor structure includes: depositing multiple decks of sacrificial layers and isolating layers, wherein the stack includes the multiple decks; and forming the gate line holes and the channel holes in each of the multiple decks by a respective etching process.

In some implementations, the method further includes removing the sacrificial layers in the stack by filling an etchant into the gate line space and forming conductive layers between the isolating layers in the stack.

In some implementations, forming the gate line structure includes: forming an outer layer of the gate line structure by depositing a dielectric material on an inner surface of the gate line space; and forming an inner layer of the gate line structure by depositing a semiconductor material into the gate line space.

A further aspect of the present disclosure features a memory system. The memory system includes a memory device and a memory controller coupled to the memory device and configured to control the memory device. The memory device includes a semiconductor structure including a stack of conductive layers and isolating layers alternating with each other along a first direction. The memory device further includes channel structures extending through the stack along the first direction. The channel structures include at least a first channel structure that has a top end and a bottom end. The first channel structure includes a channel plug in the top end. The memory device further includes a gate line structure extending through the stack along the first direction. The gate line structure includes a top portion and a body portion arranged along the first direction. The top portion is farther away from the bottom end of the first channel structure than the channel plug along the first direction.

In some implementations, a side surface of the top portion includes a curved surface and a flat surface, the flat surface is between the curved surface and the body portion along the first direction, and a side surface of the body portion includes a series of curved surfaces arranged along a second direction perpendicular to the first direction.

In some implementations, the top portion of the gate line structure extends beyond the channel plug along the first direction by a length in a range between 20 nm and 300 nm.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIGS. 1A-1F illustrate example semiconductor devices.

FIGS. 2A-2U illustrate an example process of manufacturing a semiconductor device.

FIGS. 3A-3N illustrate another example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have multiple decks, and each deck can have a large number of layers. The large number of layers and the high aspect ratio of such memory device may bring challenges to the manufacturing process. For example, an increase in depth of the memory device may introduce or exacerbate overlay (OVL) issues in the manufacturing process. In some implementations, channel holes and gate line holes can be formed in a same etching process using a same etching mask. The gate line holes can be expanded and form a gate line slit (also referred to as a gate line space). This process can be referred to as channel hole and gate line hole merging and can enlarge the process window in the manufacturing process and can mitigate or resolve the OVL issue. During the manufacturing process, channel structures are formed in the channel holes, and the gate line space is filled with a filler material such as polysilicon. Channel plugs at top ends of the channel structures can also include polysilicon. Thus, if top ends of the gate line space and the channel structures are at the same vertical level, when the polysilicon is removed from the gate line space, a protection film can be formed to protect the channel plugs. The protection film may require a separate fabrication process and may include an opening aligned with the top of the gate line space, thereby imposing strict processing window requirements and increasing the cost of the fabrication process.

Implementations of the present disclosure provide systems, devices, methods, and techniques for managing gate line structures in semiconductor devices, which can address one or more of the aforementioned issues. In some implementations, a semiconductor device includes a gate line structure and a channel structure. The gate line structure includes a top portion and a body portion arranged along a vertical direction. The top portion of the gate line structure is higher than the channel plug along the vertical direction. For example, the top portion of the gate line structure can be farther away from a bottom end of the channel structure than a channel plug of the channel structure along the vertical direction.

Implementations of the present disclosure can provide one or more of the following technical advantages and/or benefits. For example, the channel plug is lower than the top of the gate line structure and thus is protected by a dielectric layer on top of the channel plug. Thus, a separate process to form a protection film may not be needed, thereby improving the product yield and reducing the fabrication costs. A gate line space containing the gate line structure can have an opening in a trench shape, thereby resolving the OVL issue and enlarging the processing window.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

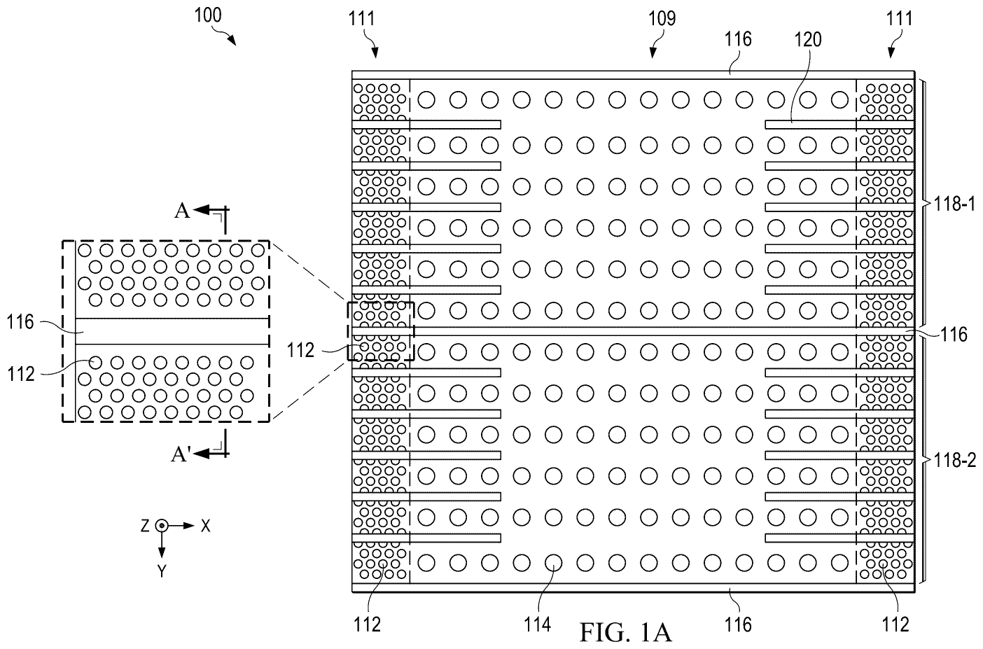

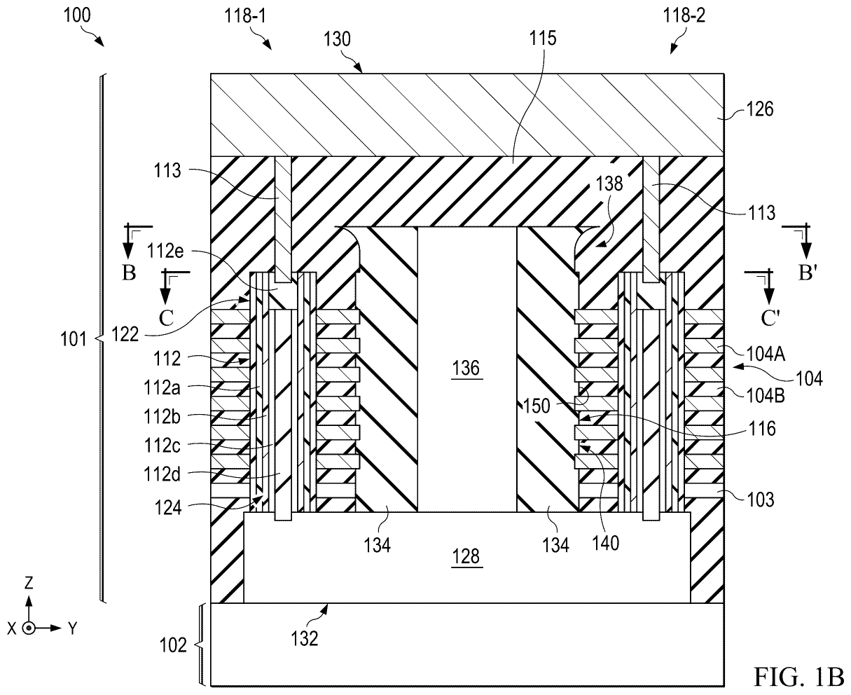

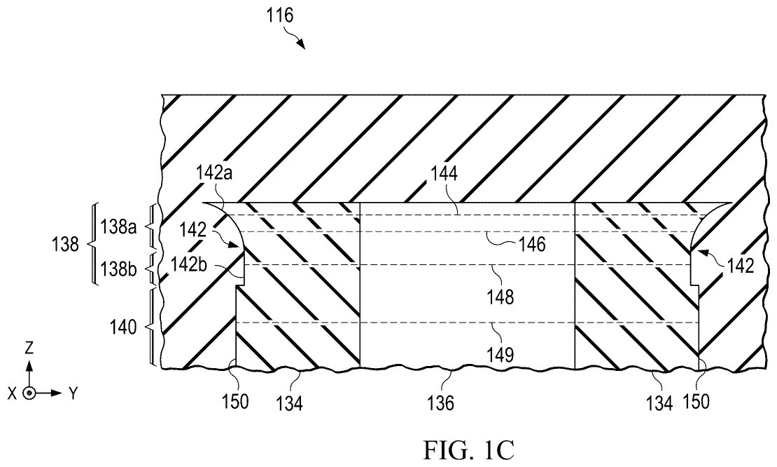

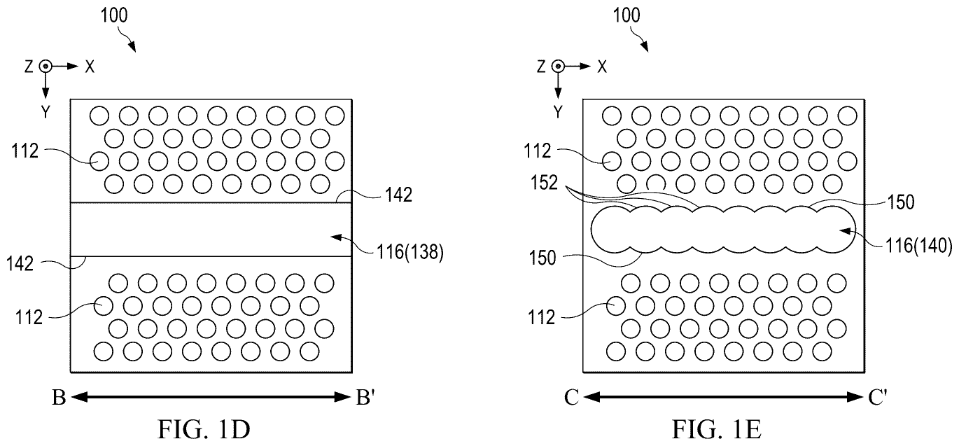

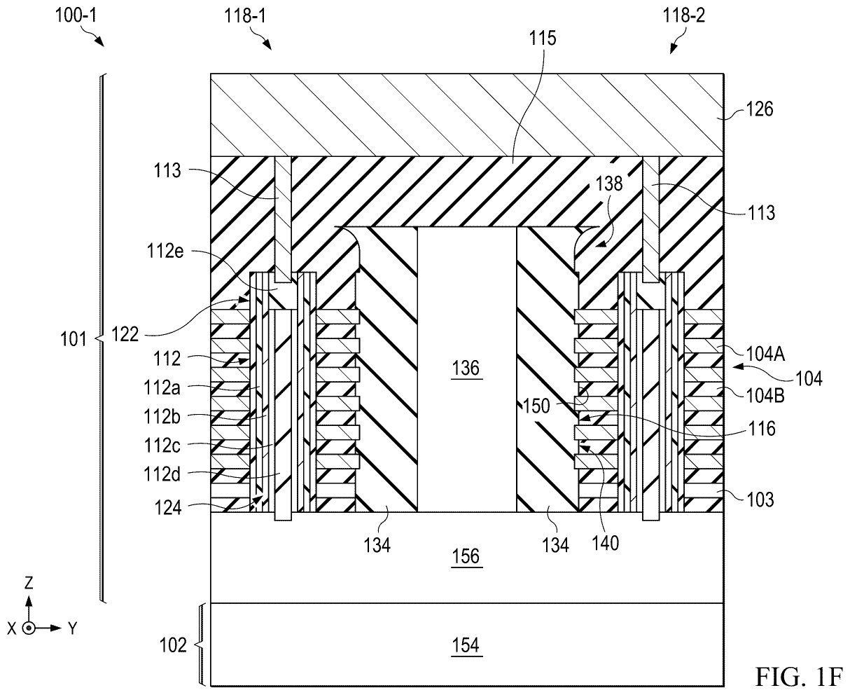

It is noted that X, Y, and Z axes (also referred to as X, Y, and Z directions) are included in FIGS. 1A-IF to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. The semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes two array regions 111 and a connection region 109 between the two array regions along a first horizontal direction (e.g., the X direction). Each array region 111 can include an array of channel structures 112. Each channel structure 112 can be used to form a string of memory cells coupled in serial along a vertical direction (e.g., Z direction) perpendicular to the first horizontal direction. In some implementations, the connection region 109 can include a staircase structure (not shown) and an array of contact structures 114 formed on the staircase structure. In some other implementations, conductive layers (e.g., the conductive layers 104A in FIG. 1B as described below) in the connection region 109 form a structure different from a staircase structure. For example, a contact structure of the array of contact structures 114 can be connected to a corresponding conductive layer and can extend through other conductive layers, and spacer for insulation can be formed between the contact structure and the other conductive layers.

In some implementations, gate line structures 116 extending in the X direction can divide an array region into multiple portions, each portion being referred to as a memory block (e.g., memory blocks 118-1 and 118-2 as shown in FIG. 1A). In some implementations, two adjacent portions 118-1 and 118-2 can be considered as a single memory block, and each of the portions 118-1 and 118-2 can be referred to as a memory finger. In some implementations, at least some gate line structures 116 can function as a common source contact for the channel structures 112 in the array regions 111. Top select gate (TSG) cuts 120 can be disposed, for example, in each of memory bocks 118-1 and 118-2 to divide the memory block into smaller portions. In some instances, each TSG cut 120 can extend through (e.g., along the vertical direction) one or more conductive layers in a top of a stack of alternating conductive layers and isolating layers (e.g., the stack 104 in FIG. 1B as described below) in the semiconductor device 100. In some implementations, the array regions 111 and the connection region 109 may include dummy channel structures or dummy memory strings (not shown) for process variation control during fabrication and/or for additional mechanical support.

FIG. 1B illustrate a cross-sectional view of the semiconductor device 100 along cut line AA′ of FIG. 1A. The semiconductor device 100 can include a semiconductor structure 101 and a semiconductor structure 102. In some implementations, the semiconductor device 100 is a bonded chip, and the semiconductor structure 101 is stacked over the semiconductor structure 102 (e.g., along the Z direction). The semiconductor structures 101 and 102 can be jointed at a bonding structure or a bonding layer (not shown in FIG. 1B) therebetween. In some implementations, the bonding structure is disposed between the semiconductor structures 101 and 102 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

The semiconductor structure 102 can include a substrate (not shown), which can include silicon (e.g., single crystalline silicon, c-Si), SiGe, GaAs, Ge, SOI, or any other suitable materials. The semiconductor structure 102 can include peripheral circuits (not shown) on the substrate. The peripheral circuits can be configured to control components (e.g., the conductive layers 104A and the channel structures 112 as described below) of the semiconductor structure 101. In some implementations, the peripheral circuits include a plurality of transistors (e.g., planar transistors and/or 3D transistors). Trench isolations (e.g., shallow trench isolations (STIs)) and doped regions (e.g., wells, sources, and drains of transistors) can be formed on or in the substrate as well. In some examples, the peripheral circuits are formed using complementary metal-oxide-semiconductor (CMOS) technology, and the semiconductor structure 102 can be formed on a semiconductor die referred to as a control die or a CMOS dic.

The semiconductor structure 101 can have two sides 130 and 132 opposite to each other along the Z direction. In some implementations, the side 132 of the semiconductor structure 101 can be bonded to the semiconductor structure 102. The side 130 is farther away from the semiconductor structure 102 and can be referred to as a top side. The side 132 can be referred to as a bottom side.

The semiconductor structure 101 can include a stack 104 of alternating conductive layers 104A and isolating layers 104B. The stack 104 can extend across both memory blocks 118-1 and 118-2. The stack 104 can extend in a second horizontal direction (e.g., Y direction) that is perpendicular to the first horizontal direction. The conductive layers 104A and the isolating layers 104B can alternate in the vertical direction (e.g., Z direction) perpendicular to the second horizontal direction. The conductive layers 104A can be the same or different from each other in thickness, for example, ranging from 10-500 nm, e.g., about 35 nm. The isolating layers 104B can also be the same or different from each other in thickness, for example, ranging from 10-500 nm, e.g., about 25 nm. It should be noted that the number of the conductive layers 104A and the isolating layers 104B shown in FIG. 1B is for illustration only and that any suitable number of the conductive layers 104A and the isolating layers 104B can be included in the stack 104. In some implementations, the stack 104 can include multiple decks stacked along the vertical direction (e.g., the Z direction). Each of the multiple decks can include a subset of the conductive layers 104A and the isolating layers 104B in the stack 104.

The conductive layers 104A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 104B can include a dielectric material, such as silicon oxide, silicon nitride, silicon oxynitride, or any combination thereof. In some implementations, the isolating layers 104B can also include high-K dielectric materials, such as hafnium oxide, zirconium oxide, aluminum oxide, tantalum oxide, lanthanum oxide, or any combination thereof. In some implementations (not shown in FIG. 1B), the stack 104 includes liner layers. A liner layer can cover part or all sides of a corresponding conductive layer 104A and be between the conductive layer 104A and two isolating layers 104B adjacent to the corresponding conductive layer 104A. The liner layer can include a high-K dielectric material (e.g., Al₂O₃). In some examples, the conductive layer 104A includes a metallic material (e.g., W) and an adhesive material (e.g., TiN), and the adhesive material can be deposited between the metallic material and the high-K dielectric material. In some examples, the conductive layer 104A includes the metallic material (e.g., W), and the liner layer includes the adhesive material (e.g., TiN) and the high-K dielectric material.

In some implementations, the semiconductor structure 101 can further include a semiconductor layer 103 between the stack 104 and the semiconductor structure 102 along the vertical direction. The semiconductor layer 103 can include any suitable semiconductor material (e.g., polysilicon). In some implementations, the semiconductor layer 103 can be removed from the semiconductor structure 101 in a later process of manufacturing the semiconductor device 100.

As shown in FIG. 1B, each memory block (e.g., memory block 118-1 or 118-2) of the semiconductor device 100 includes channel structures 112 extending through the stack 104 along the vertical direction. Each channel structure 112 can be in the shape of a cylinder or a pillar, and can include a high-K layer 112a, a block layer surrounded by the high-K layer, a charge trapping layer (or a storage layer) surrounded by the block layer, a tunneling layer surrounded by the charge trapping layer, a channel layer 112c surrounded by the tunneling layer, and a core filler layer 112d surrounded by the channel layer 112c, and a channel plug 112e formed above the core filler layer 112d and being in contact with the channel layer 112c. In some implementations, the channel layer 112c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film 112b, can include ONO dielectrics (silicon Oxide-silicon Nitride-silicon Oxide).

Each channel structure 112 has two ends 122 and 124 disposed opposite to each other along the Z direction. The end 122 is closer to the top side 130 of the semiconductor structure 101. The channel plug 112e of the channel structure 112 is in the end 122. The semiconductor structure 101 can further include an interconnect layer 126 adjacent to the top side 130. The channel plug 112e of each channel structure 112 can be coupled to the interconnect layer 126 (e.g., through a vertical conductive structure 113 as shown in FIG. 1B). An isolating structure 115, which can include dielectric materials such as silicon oxide, can be formed in between the vertical conductive structures 113 to isolate the vertical conductive structures 113. The interconnect layer 126 can include interconnects and can transfer electrical signals between the channel structures 112 and outside circuits, e.g., for pad-out purposes. In some implementations, the end 124 of each channel structure 112 is connected to a semiconductor layer 128 adjacent to the bottom side 132. For example, the high-K layer 112a and the memory film 112b (e.g., ONO) at the end 124 can be removed to expose the channel layer 112c (e.g., polysilicon). The channel layer 112c at the end 124 can be connected to the semiconductor layer 128. The semiconductor layer 128 can be made of any suitable semiconductor materials (e.g., polysilicon) and can function as an array common source of memory strings (e.g., channel structures 112) of the semiconductor device 100.

As illustrated in FIG. 1A, one or more gate line structures 116 can be formed within the array region 111 in the first horizontal direction (e.g., the X direction) to divide the semiconductor device 100 into multiple memory blocks (e.g., memory blocks 118-1 and 118-2). A cross-sectional view of one of the gate line structures 116 is illustrated in FIG. 1B. The gate line structure 116 extends along the first horizontal direction (e.g., the X direction) and is between the memory block 118-1 and the memory block 118-2 (e.g., as shown in FIG. 1A). As shown in FIG. 1B, the gate line structure 116 extends through the stack 104 and the semiconductor layer 103 along the vertical direction (e.g., the Z direction) perpendicular to the first horizontal direction (e.g., the X direction) and the second horizontal direction (e.g., the Y direction). The gate line structure 116 can insulate the conductive layers 104A of the memory block 118-1 from the conductive layers 104A of the memory block 118-2. For example, the gate line structure can be in contact with a sidewall of the memory block 118-1 and a sidewall of the memory block 118-2 along the Y direction.

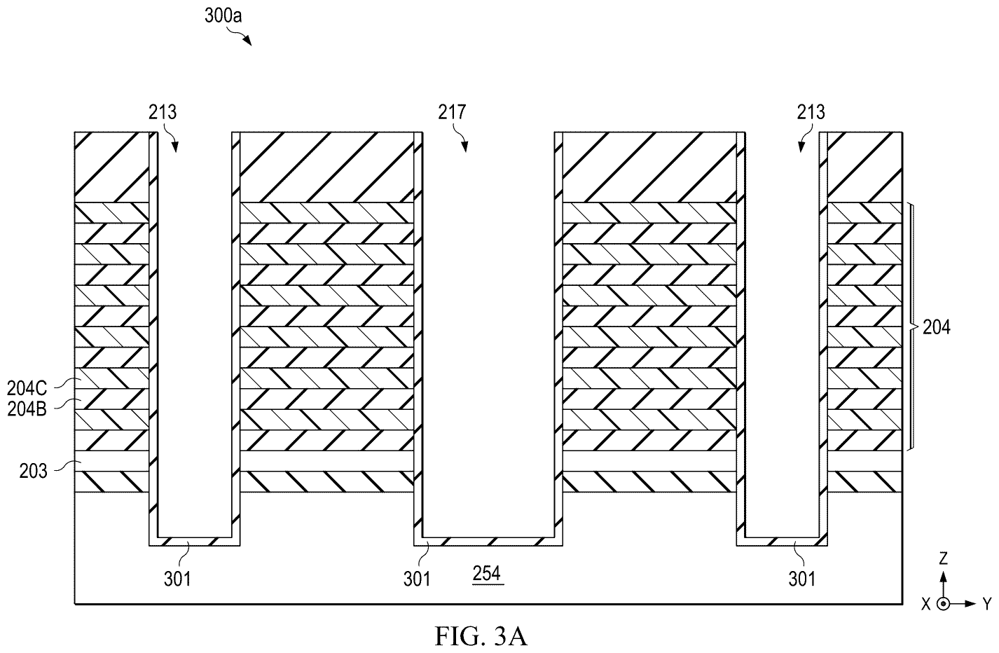

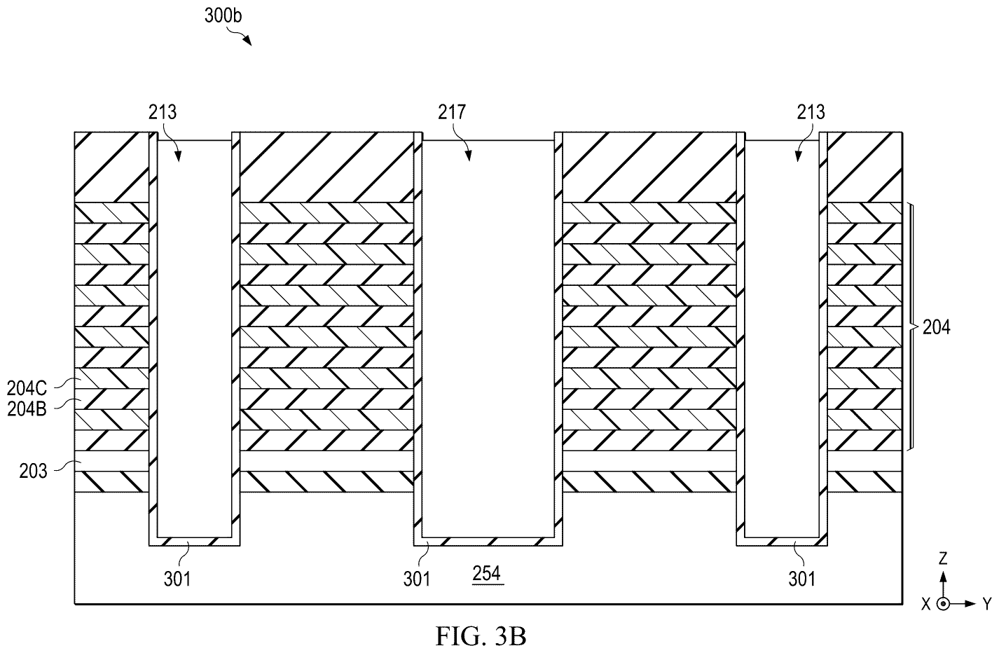

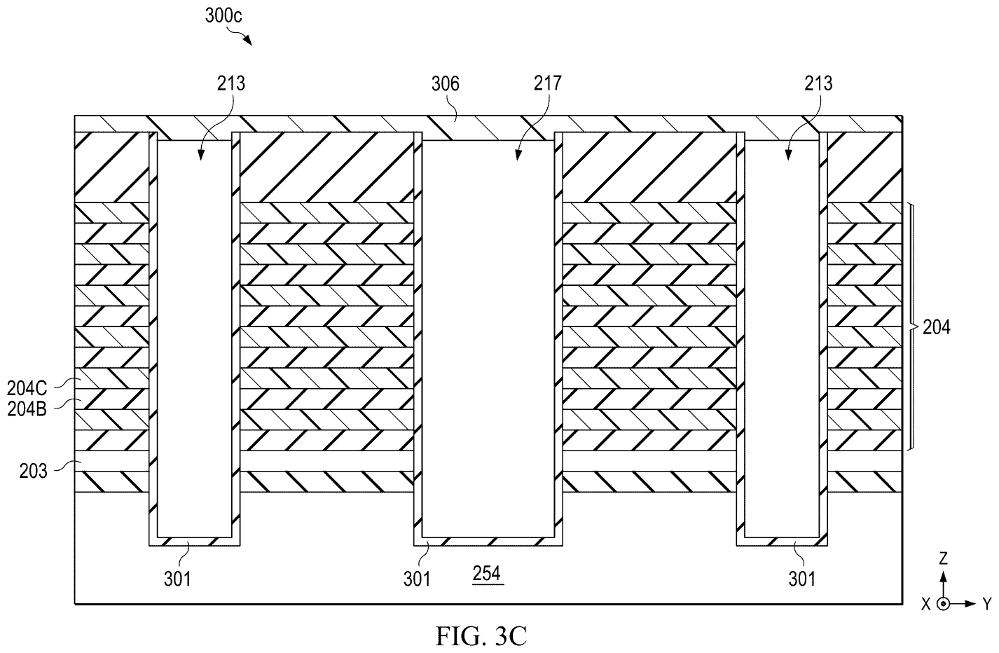

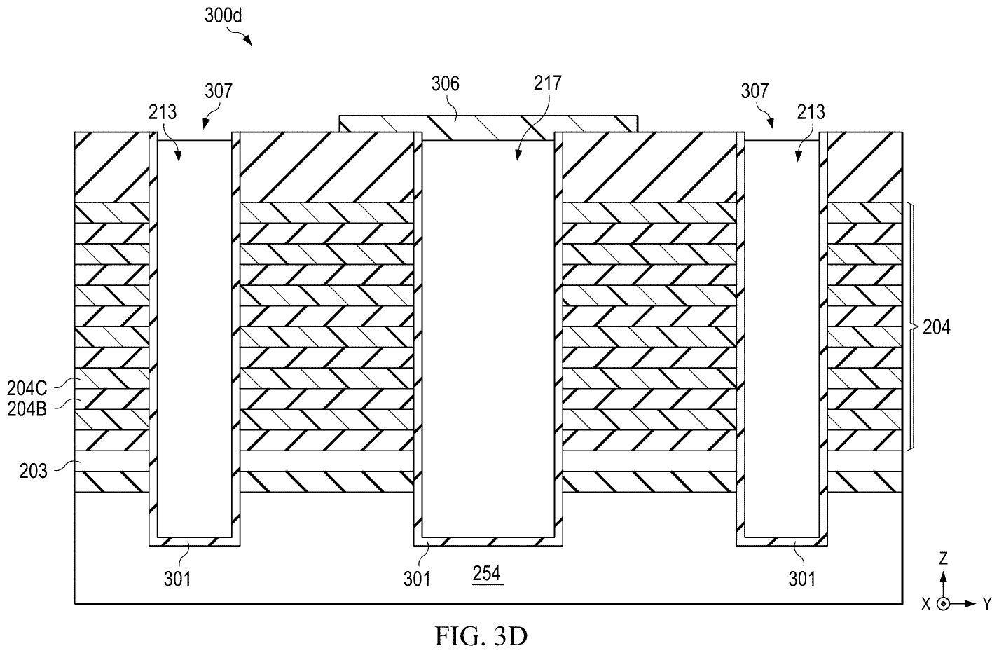

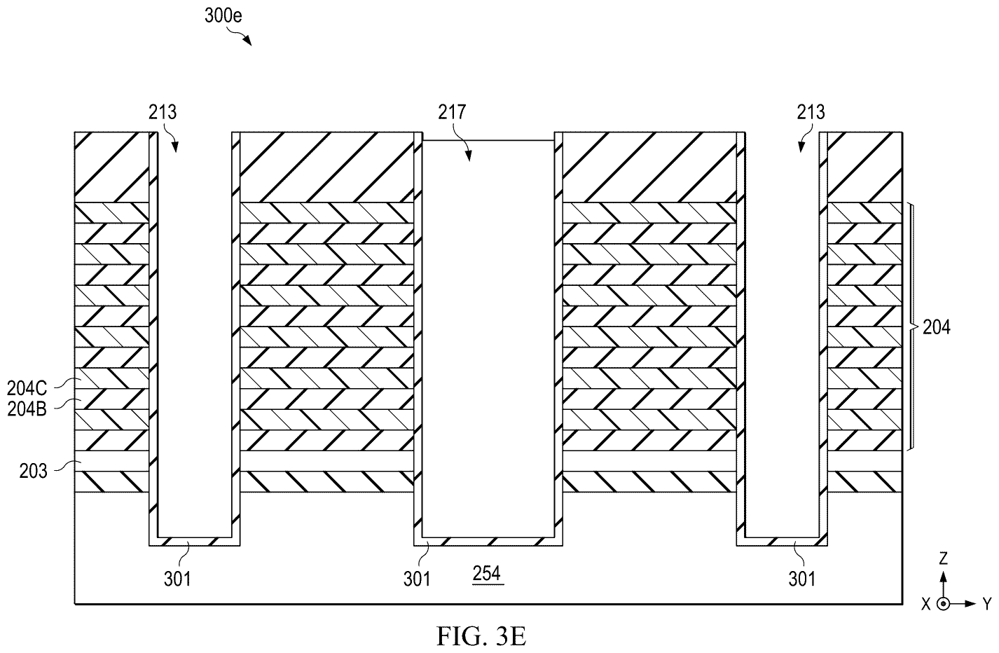

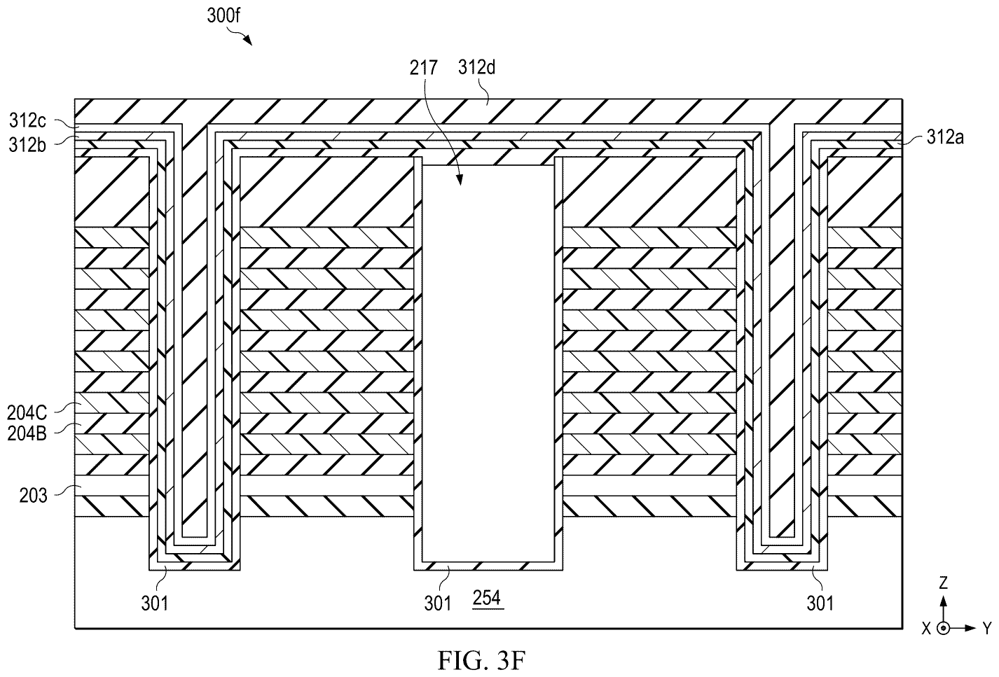

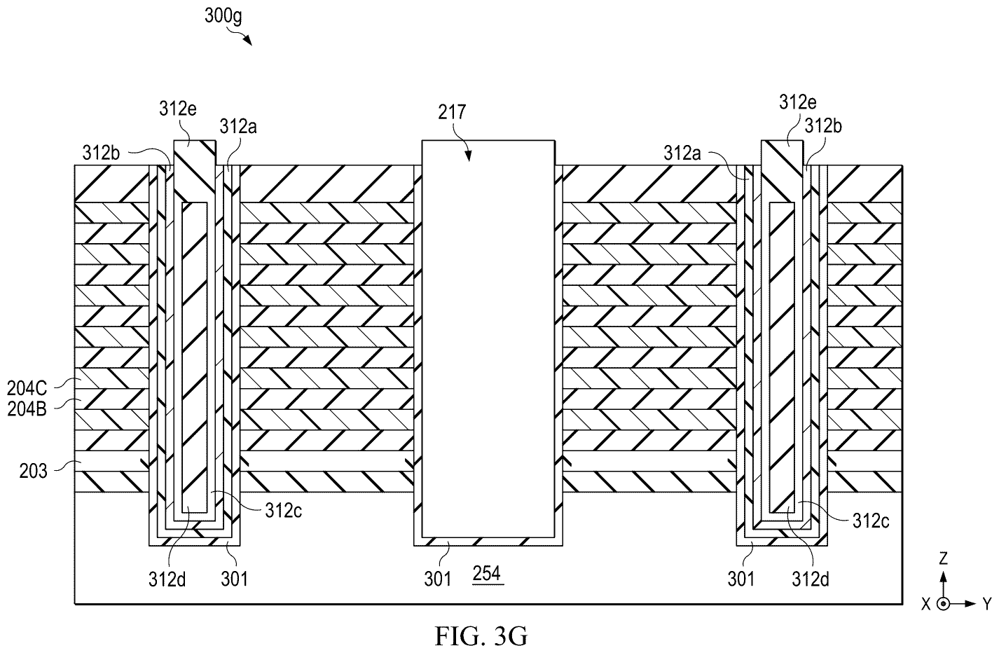

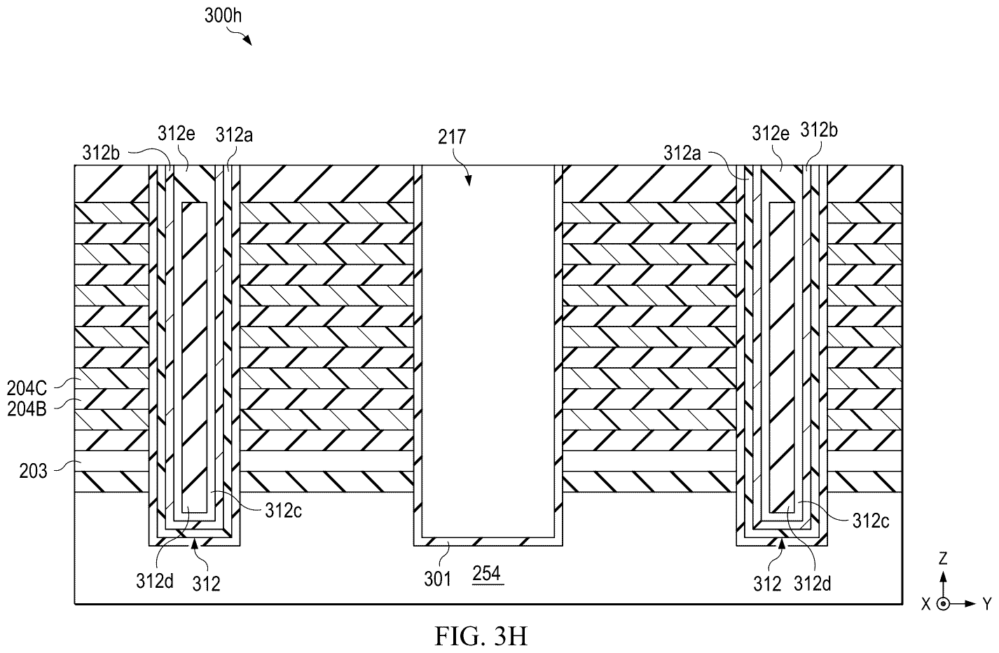

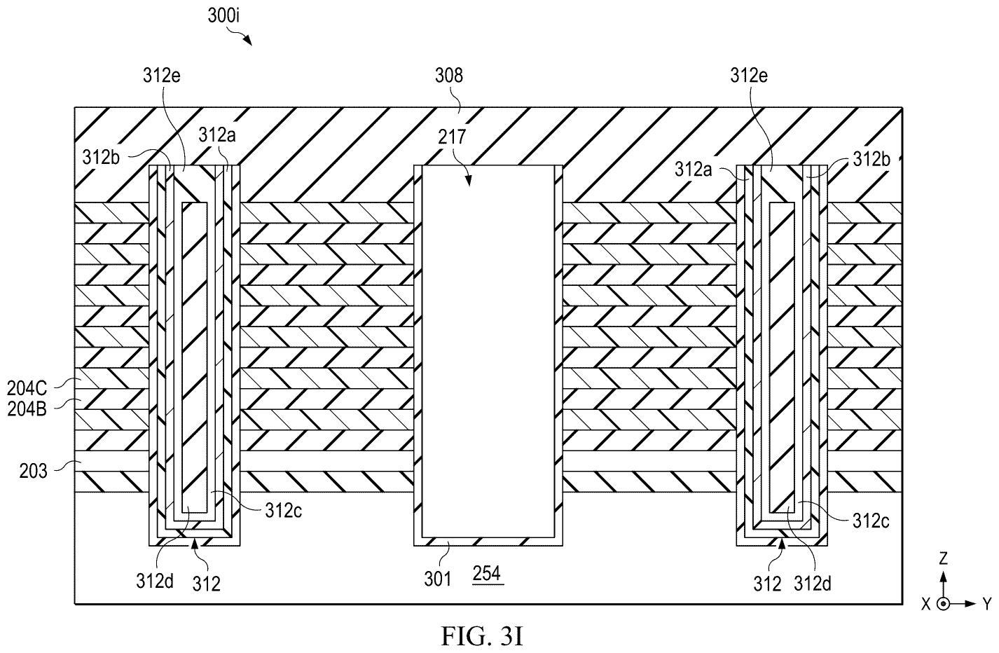

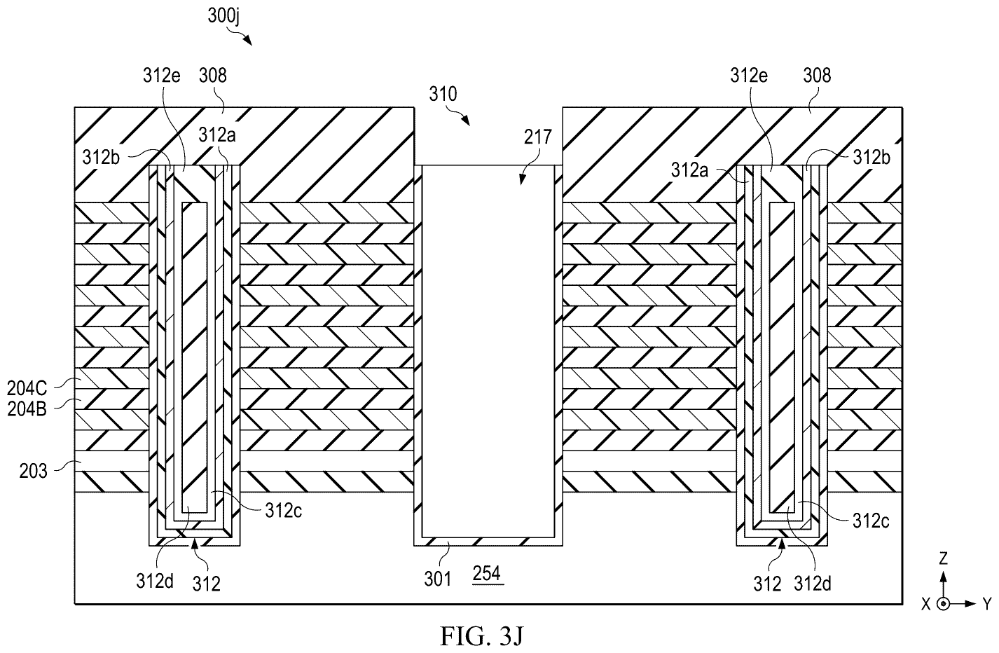

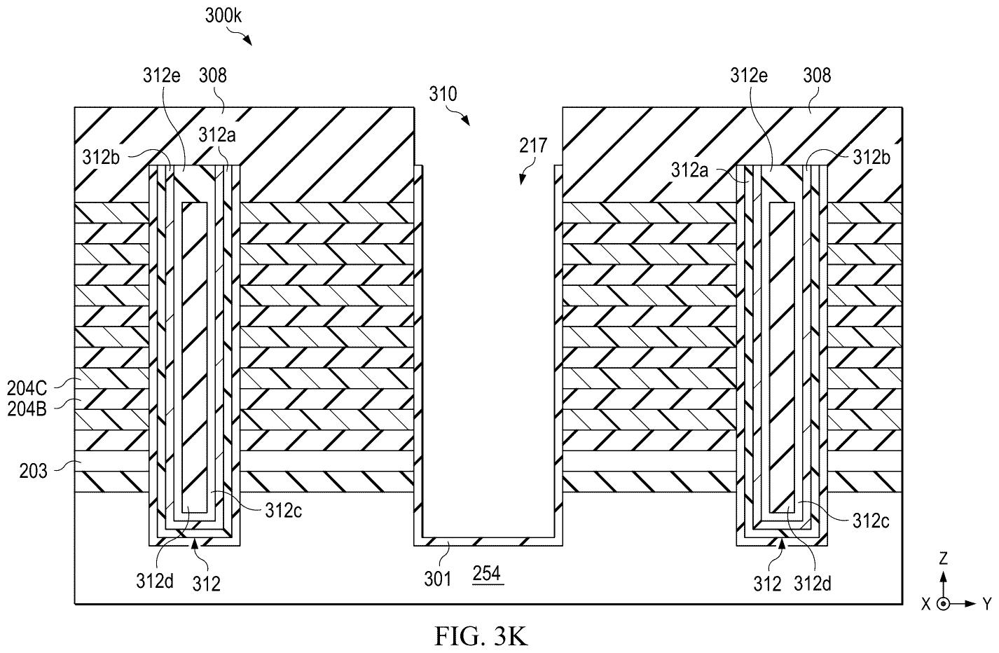

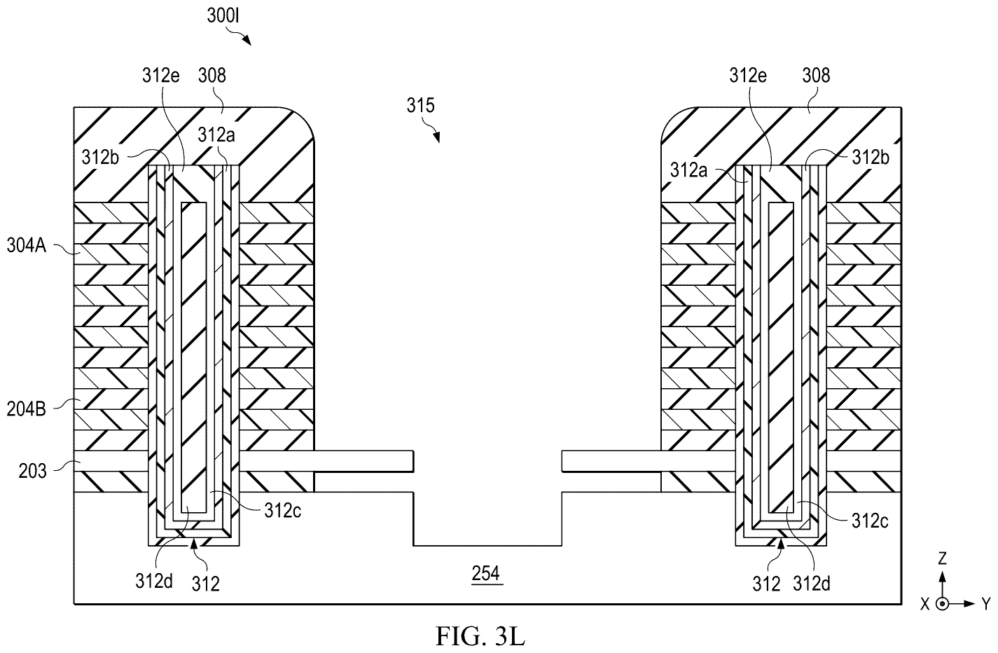

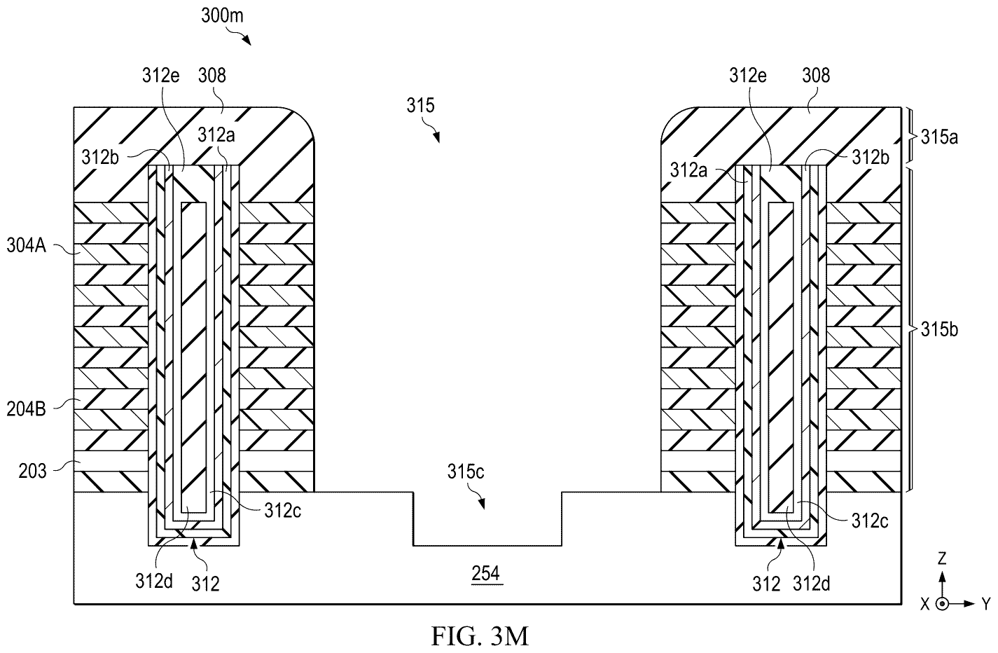

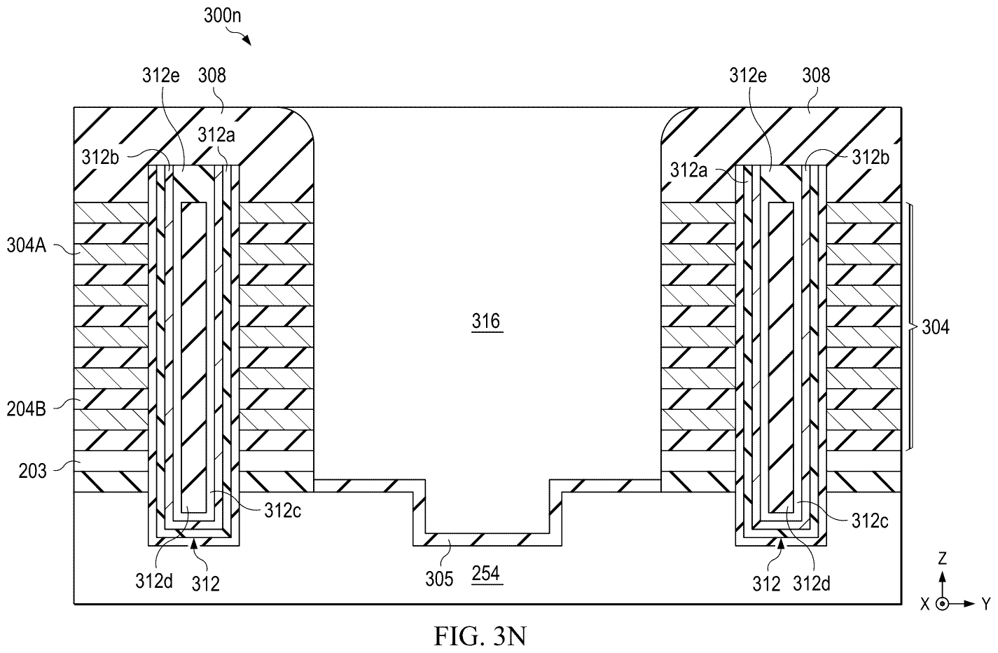

The gate line structure 116 includes a top portion 138 and a body portion 140 arranged along the Z direction. The top portion 138 of the gate line structure 116 is farther away from the bottom end 124 of the channel structure 112 than the channel plug 112e along the Z direction. In some implementations, the top portion 138 of the gate line structure 116 can extend beyond the channel plug 112e along the Z direction by a length between 20 nanometers (nm) and 300 nm. For example, a distance (along the Z direction) between top ends (ends that are closer to the top side 130 of the semiconductor structure 101) of the gate line structure and the channel plug 112e can be in a range between 50 nm and 150 nm. In some implementations (e.g., as shown in FIG. 1A), the gate line structure 116 can have an outer layer 134 and an inner layer 136 (e.g., in each of the top portion 138 and the body portion 140) surrounded by the outer layer. The outer layer 134 includes a dielectric material (e.g., silicon oxide), and the inner layer 136 includes a semiconductor material (e.g., polysilicon). The semiconductor layer 128 can be connected to the body portion 140 (e.g., an end of the inner layer 136 closer to the bottom side 132 of the semiconductor structure 101) of the gate line structure 116. In some other implementations (e.g., the gate line structure 316 of FIG. 3N), the gate line structure 116 can be a solid semiconductor structure made of a suitable semiconductor material such as polysilicon.

FIG. 1C illustrates an enlarged view of the gate line structure 116. As shown in FIG. 1C, the top portion 138 has two side surfaces 142 opposite to each other along the Y direction with regards to the inner layer 136. The body portion 140 also has two side surfaces 150 opposite to each other along the Y direction with regards to the inner layer 136. The top portion 138 includes a first portion 138a and a second portion 138b arranged along the Z direction. The second portion 138b is connected to the body portion 140 of the gate line structure 116. The first portion 138a is farther away from the body portion 140 than the second portion 138b along the Z direction. Each side surface 142 includes a curved surface 142a (e.g., a side surface of the first portion 138a) and a flat surface 142b (e.g., a side surface of the second portion 138b). The flat surface 142b is between the curved surface 142a and the body portion 140 along the Z direction. The flat surface 142b can be a smooth surface absent of lumps or indentations. In some implementations, a size (e.g., a maximum size) of the first portion 138a along the Y direction can gradually increase along the Z direction. For example, a cross section 144 of the first portion 138a and a cross section 146 of the first portion 138a are in contact with the curved surface 142a and are perpendicular to the Z direction. The cross section 144 is farther away from the body portion 140 than the cross section 146 along the Z direction. A size (e.g., a maximum size) of the cross section 144 along the Y direction is larger than a size (e.g., a maximum size) of the cross section 146 along the Y direction. In some examples, the size can be a length along the Y direction.

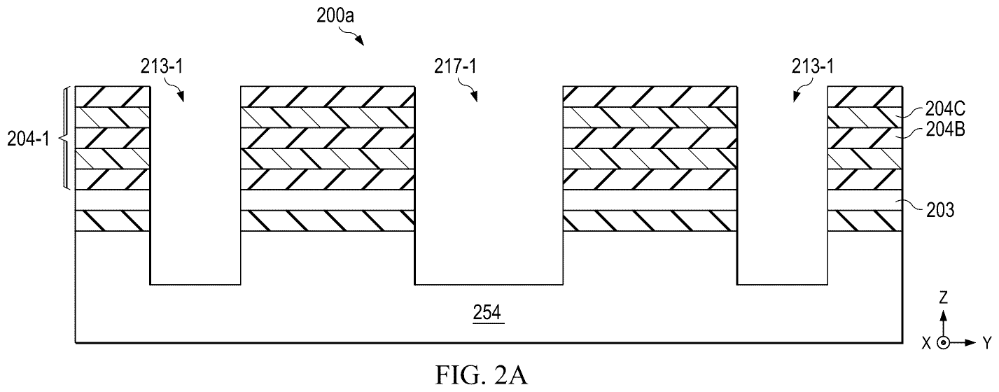

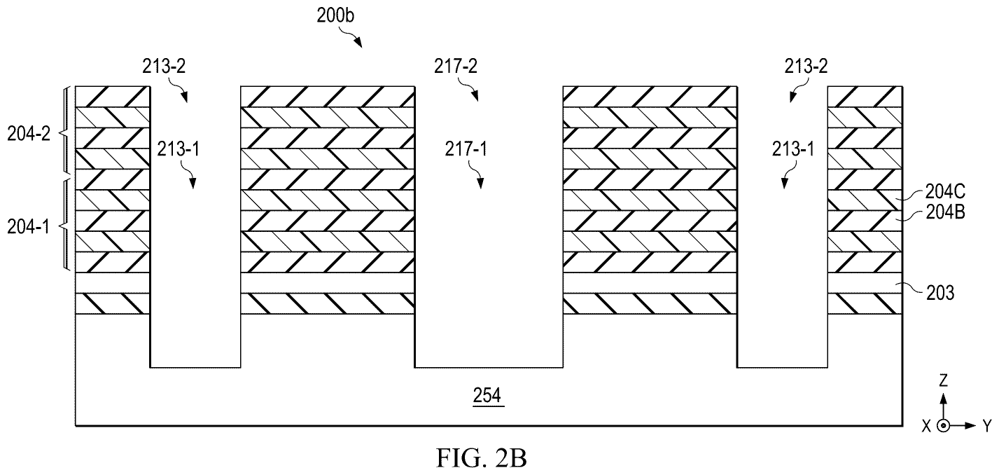

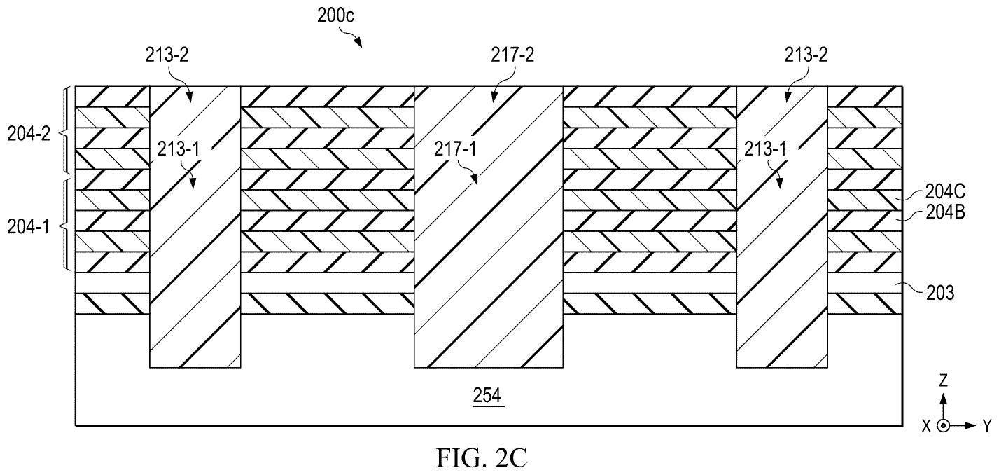

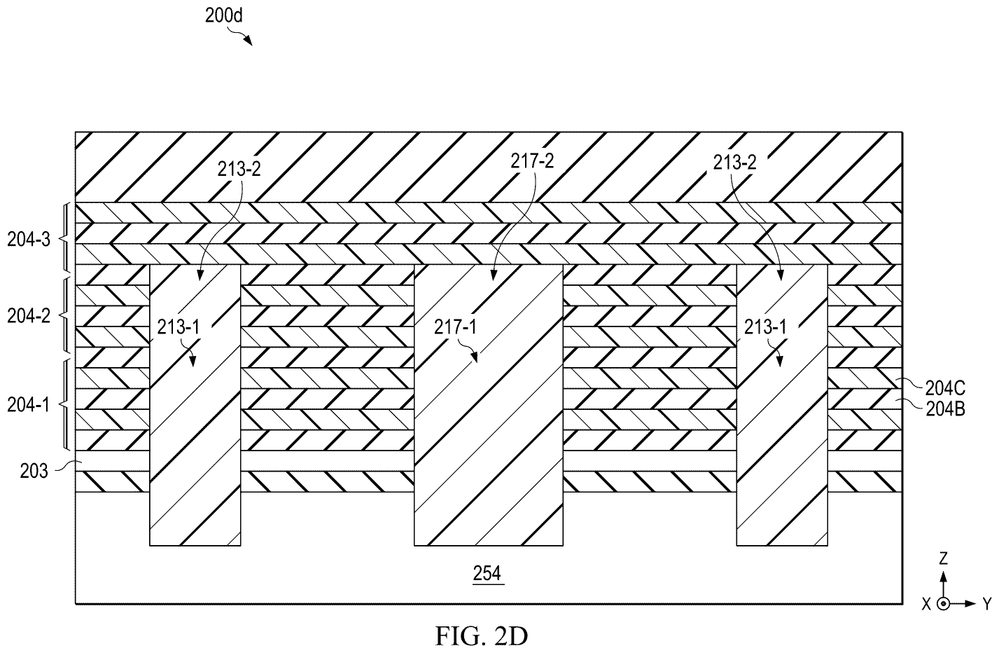

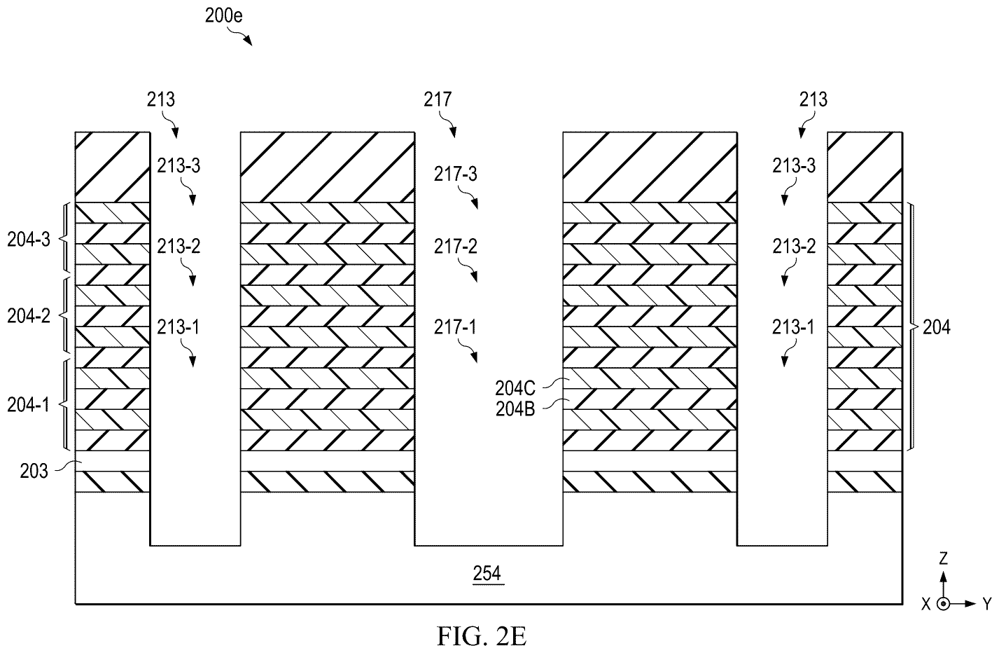

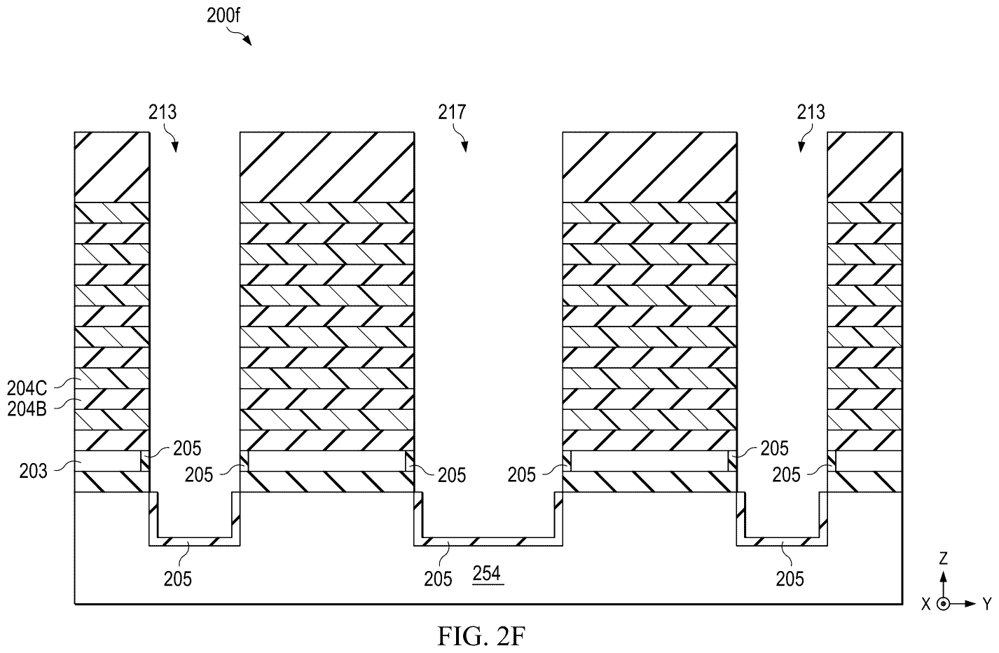

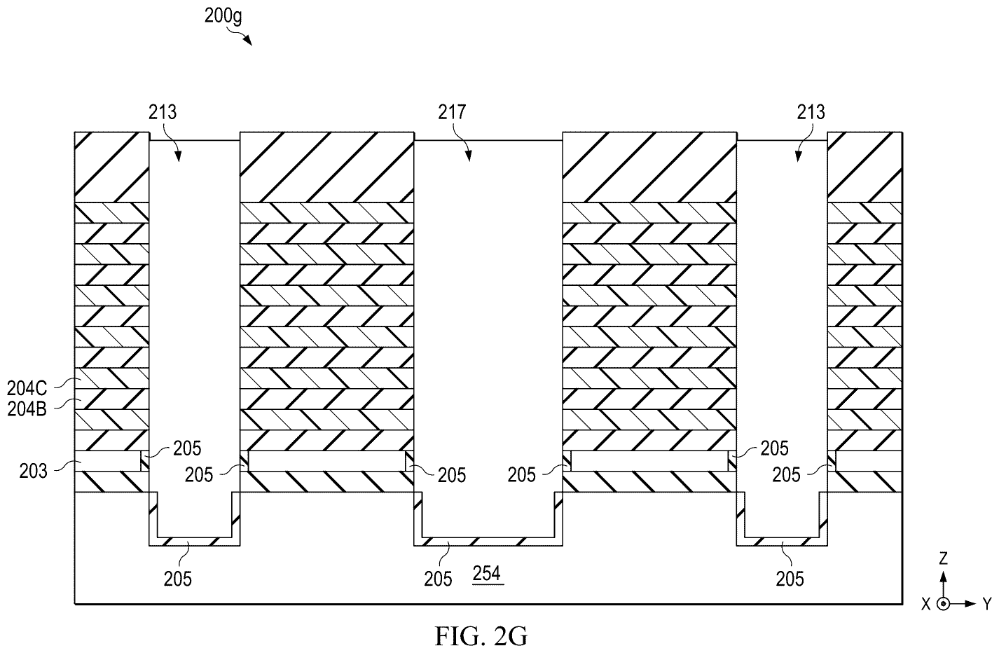

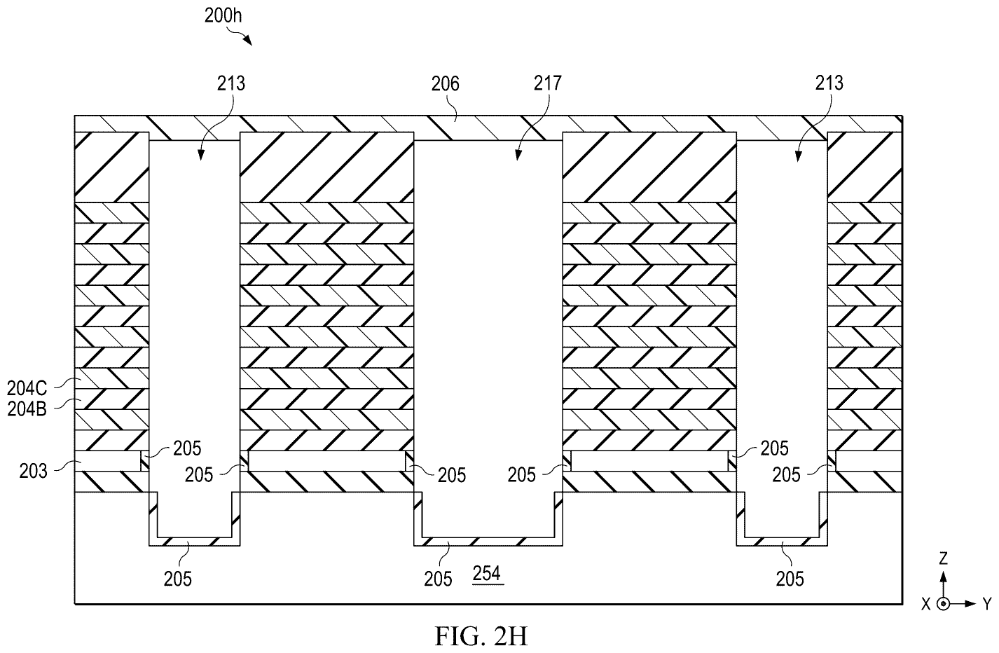

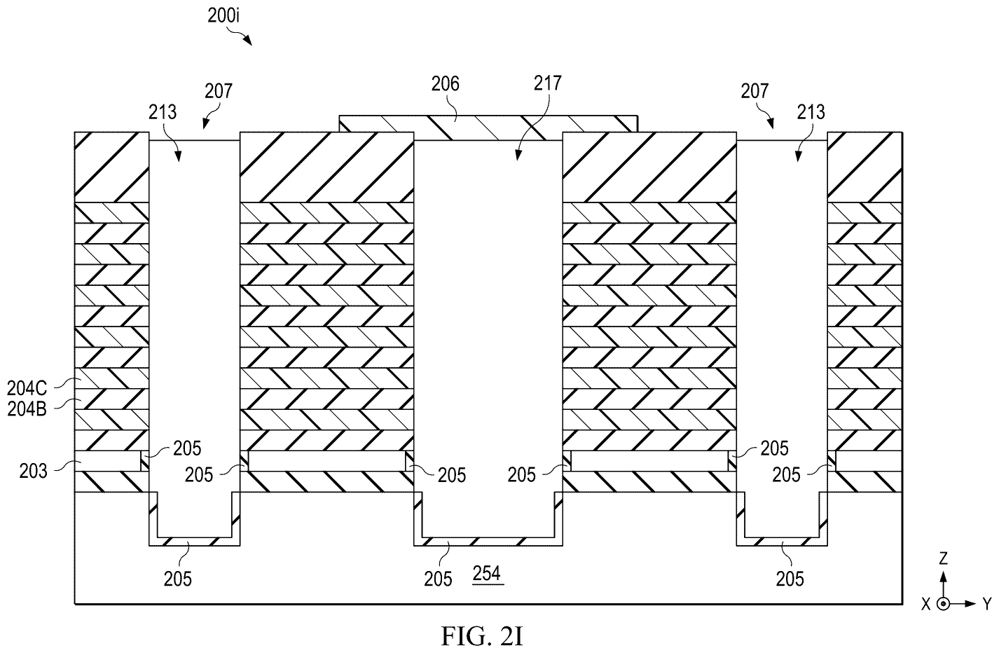

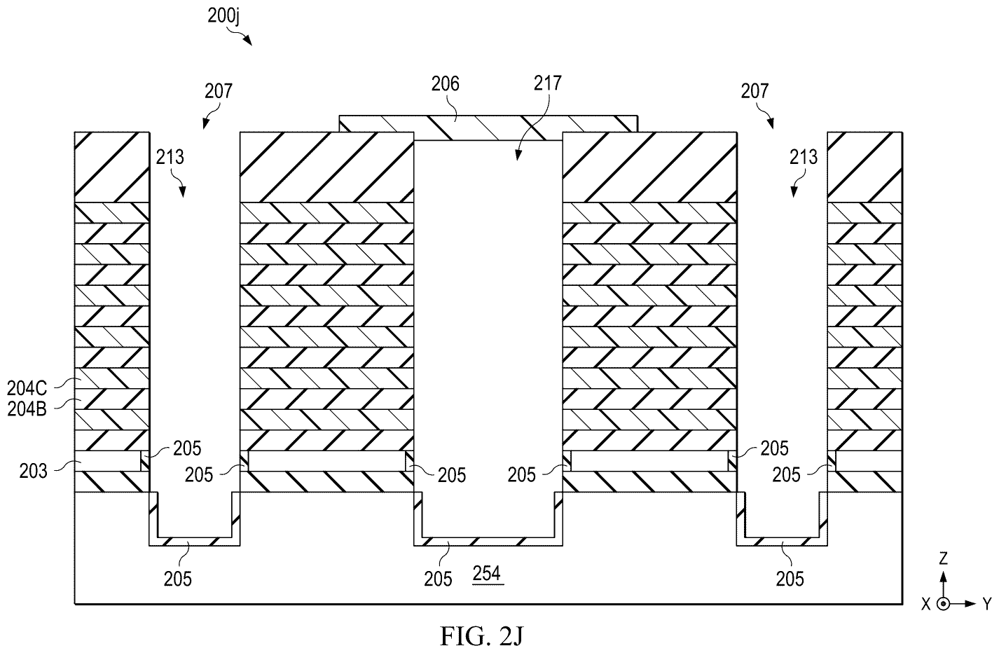

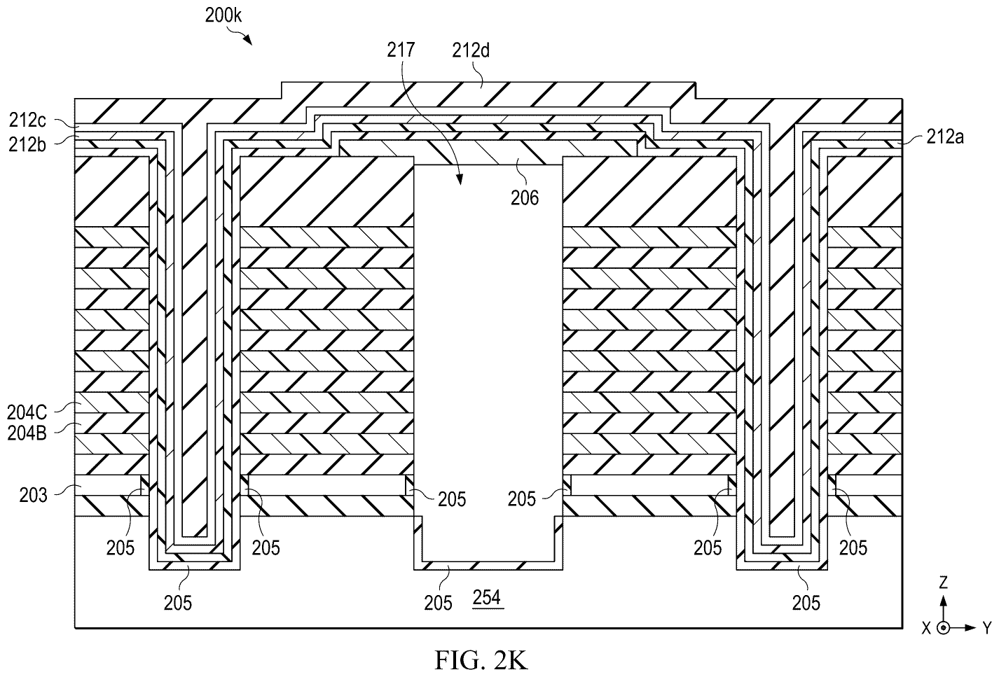

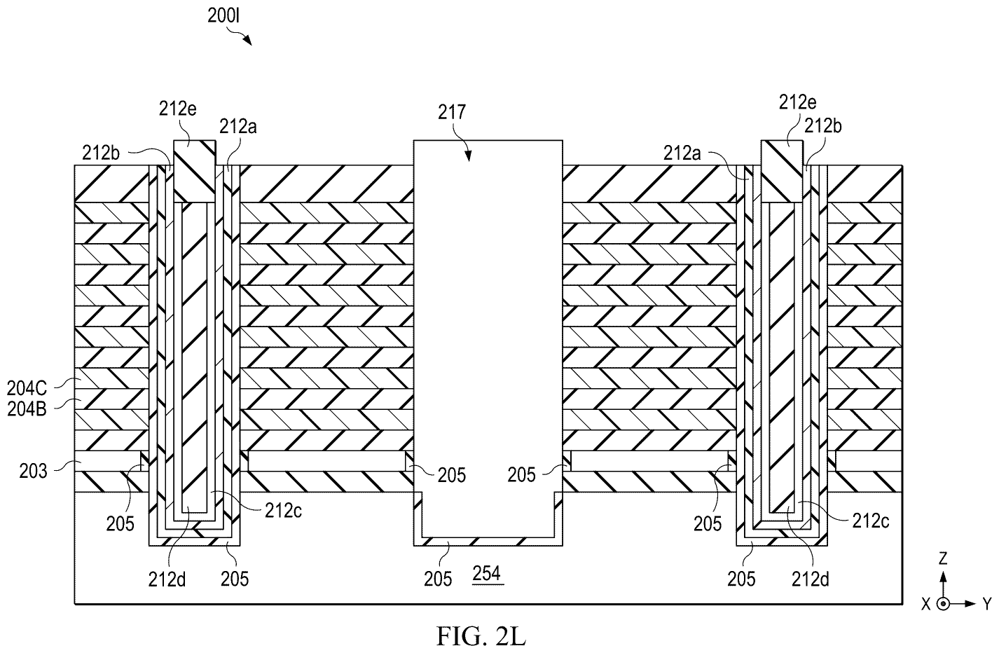

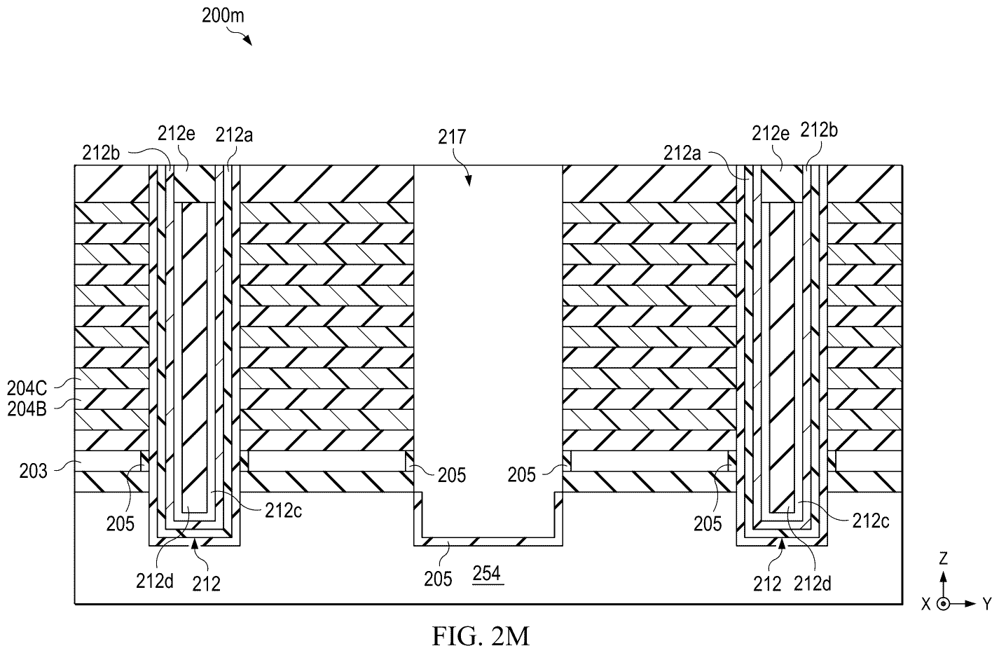

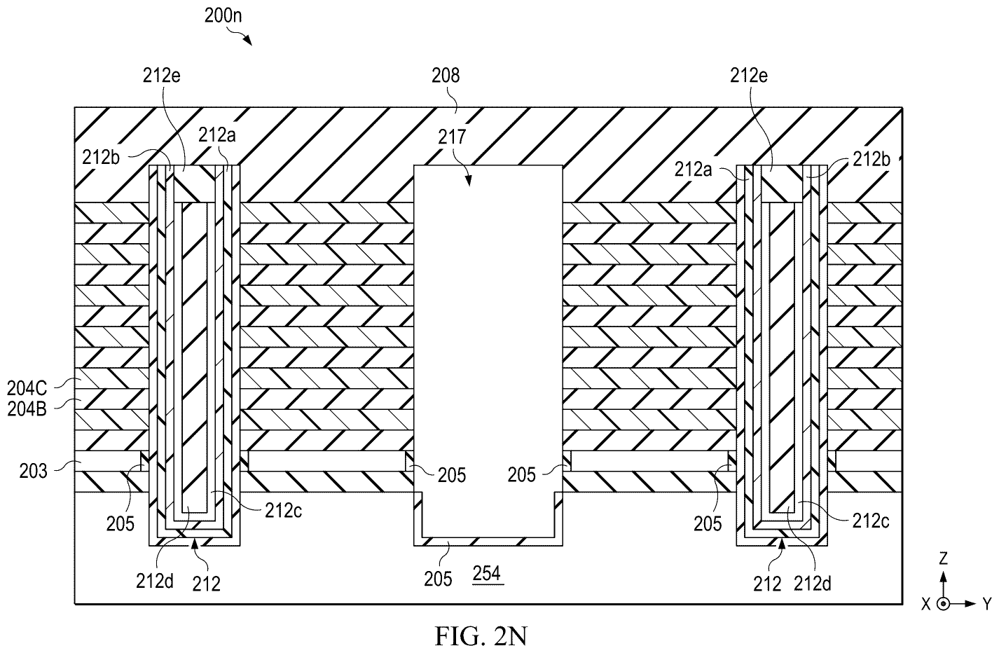

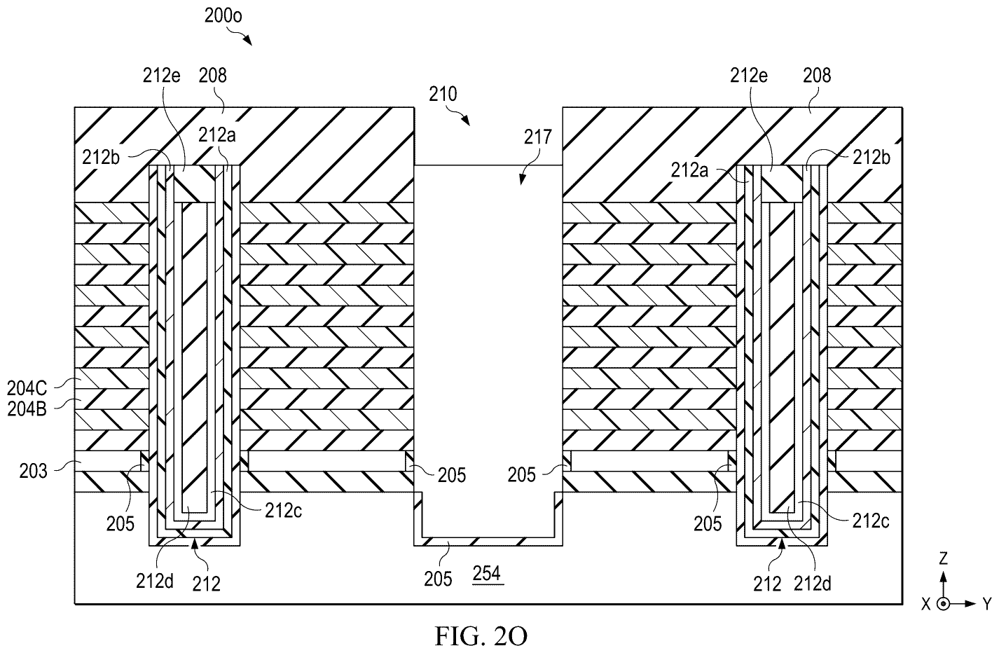

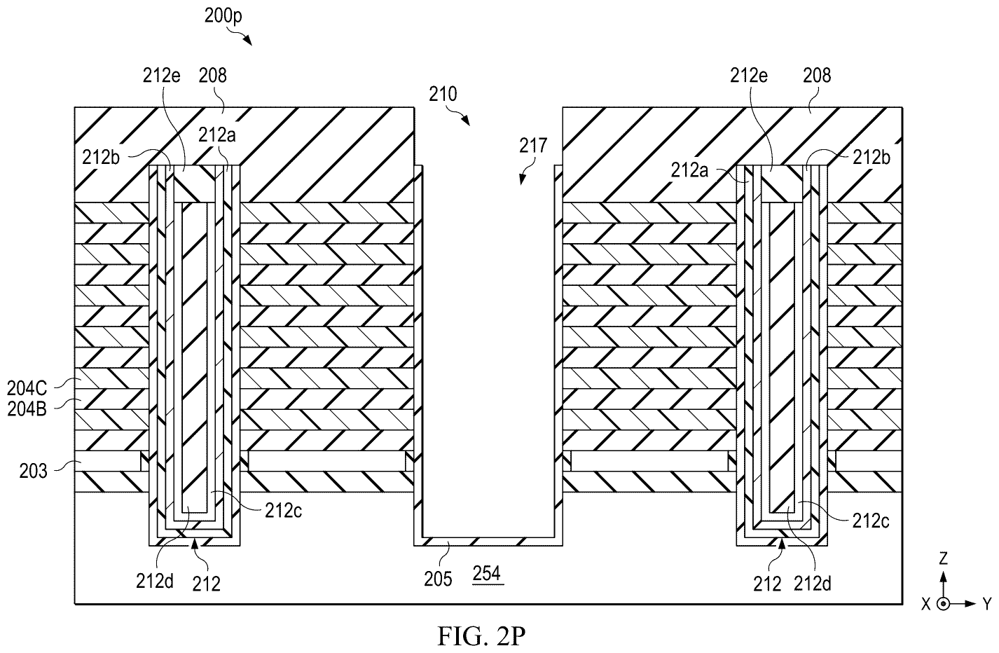

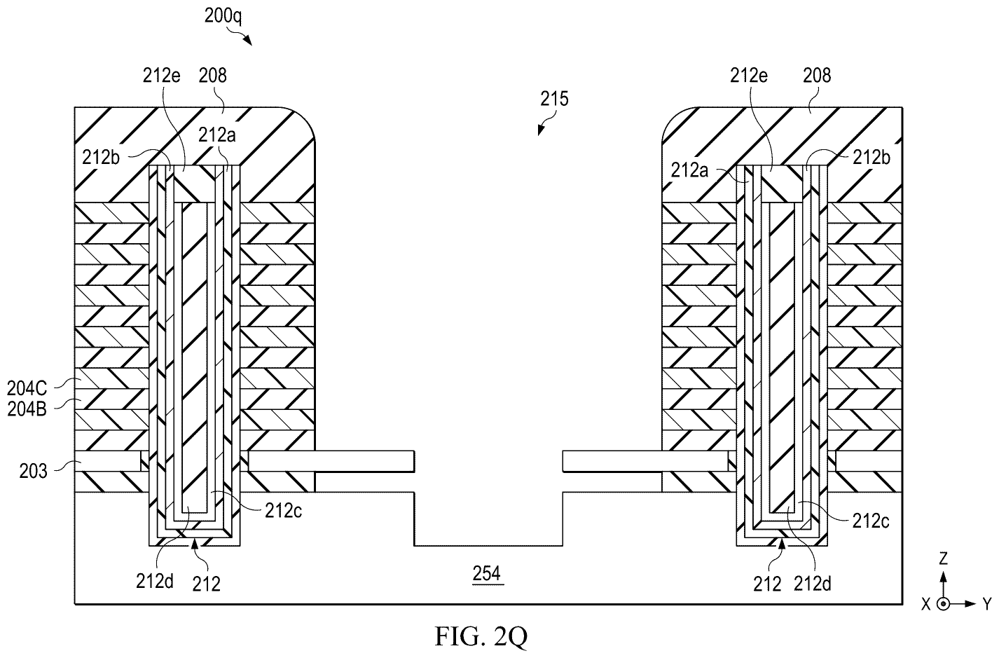

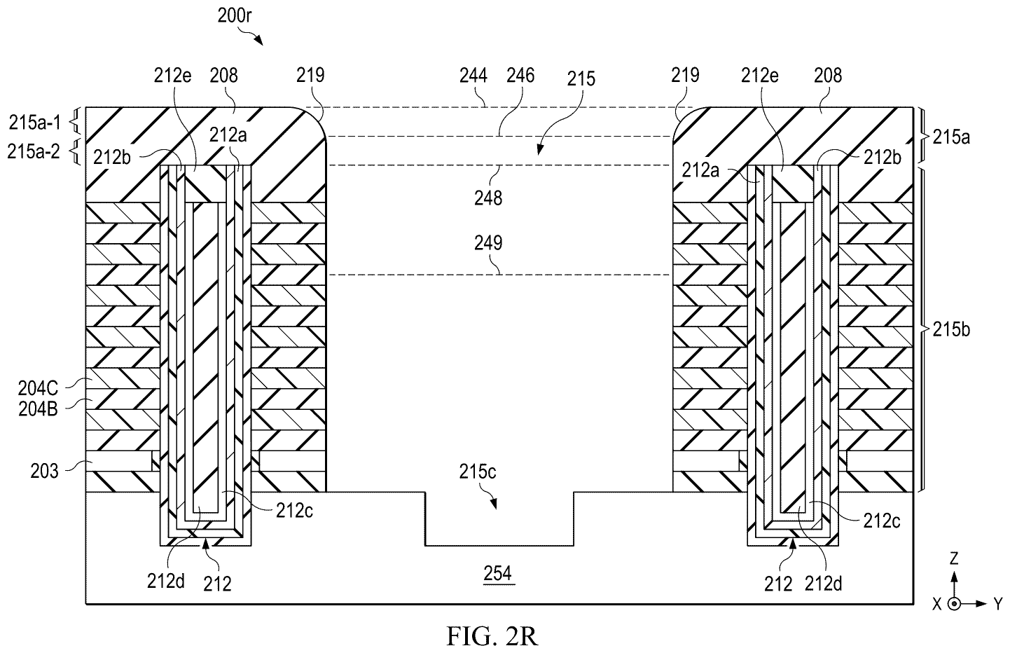

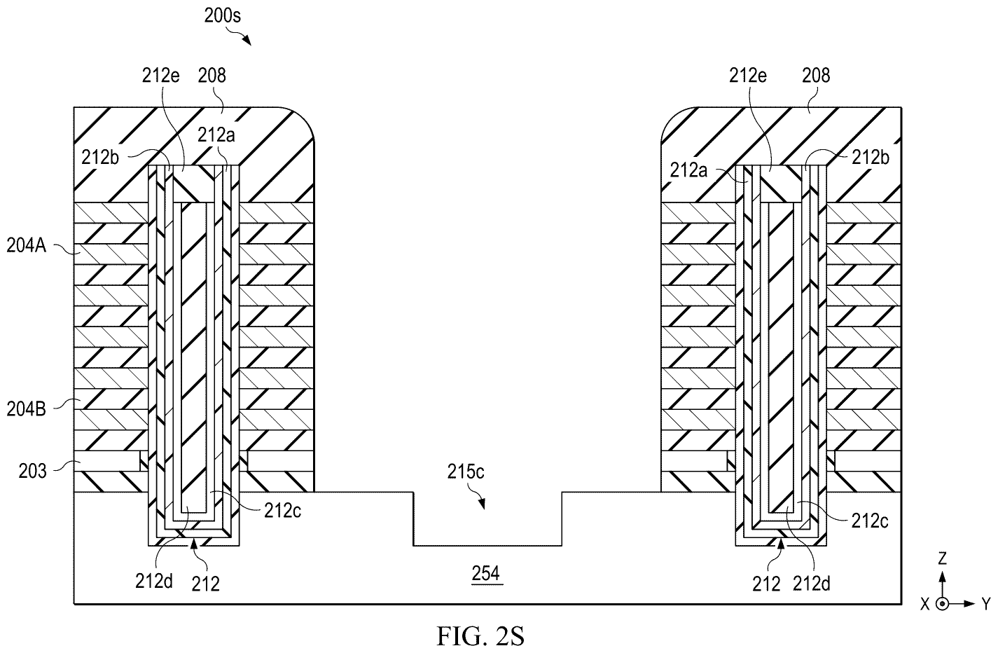

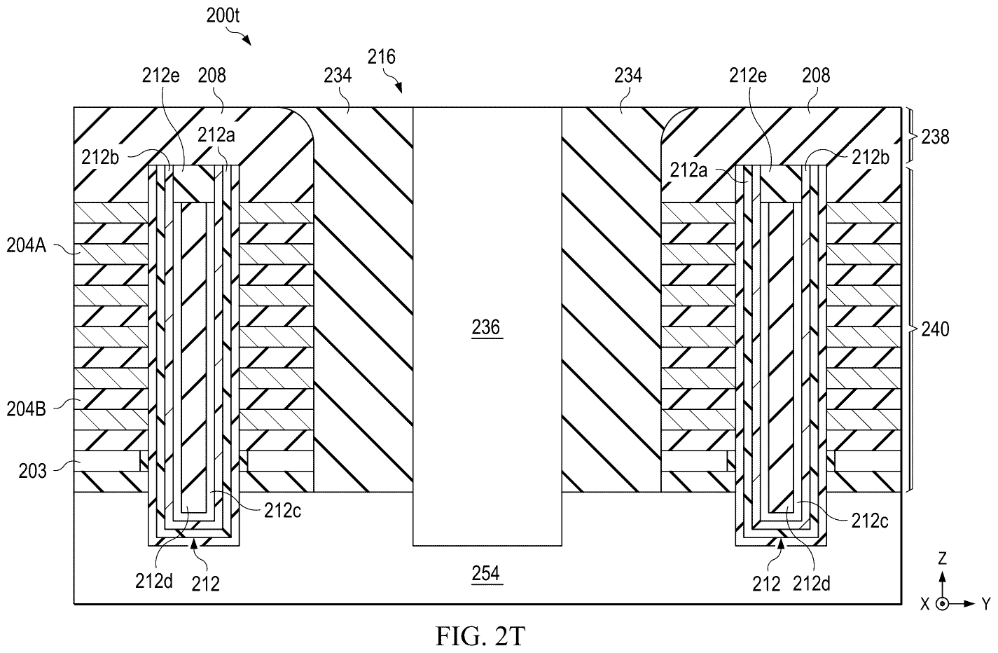

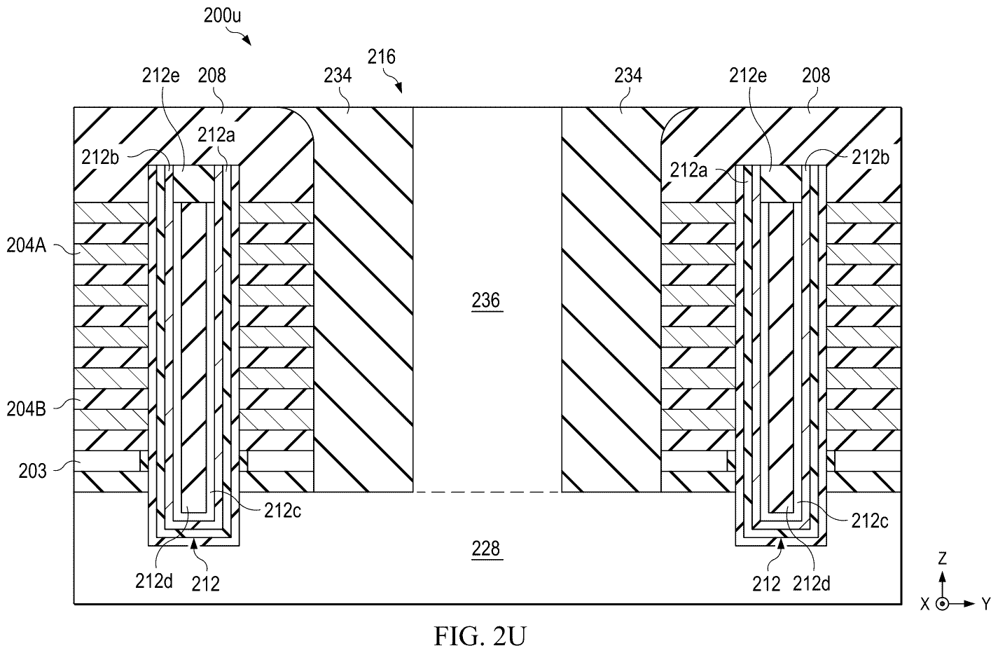

A size (e.g., a maximum size) of the first portion 138a along the Y direction can be larger than or equal to a size (e.g., a maximum size) of the second portion 138b along the Y direction. In some implementations, the size of the second portion 138b along the Y direction can be uniform along the Z direction. In some implementations, the size of the second portion 138b along the Y direction can be smaller than a size (e.g., a maximum size) of the body portion 140 along the Y direction. For example, a cross section 148 of the second portion 138b is in contact with the flat surface 142b and is perpendicular to the Z direction. A cross section 149 of the body portion 140 is in contact with the surface 150 and is perpendicular to the Z direction. A size (e.g., a maximum size) of the cross section 148 along the Y direction is smaller than a size (e.g., a maximum size) of the cross section 149 along the Y direction. It is understood that the example illustrated by FIG. 1C is only for illustration and is not intended to be limiting. In some implementations (e.g., as shown in FIGS. 2R and 2T), the size of the second portion 138b along the Y direction can be same as the size of the body portion 140 along the Y direction. In some other implementations, the size of the second portion 138b along the Y direction can be larger than the size of the body portion 140 along the Y direction.

FIGS. 1D-1E illustrate cross-sectional views of the semiconductor device 100 along cut lines BB′ and CC′ of FIG. 1A. As shown in FIG. 1D, the side surfaces 142 of the top portion 138 of the gate line structure 116 can have a uniform profile along the X direction. As shown in FIG. 1E, a lateral cross section of the body portion 140 of the gate line structure 116 is in a shape of partial circles arranged in the X direction and connected together. Each side surface 150 of the body portion 140 includes a series of curved surfaces 152 arranged along the X direction. In other words, the side surface 150 includes wavy patterns (e.g., 152) repeating along the X direction.

FIG. 1F illustrates a semiconductor device 100-1, which is another implementation of the semiconductor device 100. The semiconductor device 100-1 includes the stack 104, the semiconductor layer 103, the channel structures 112, the gate line structure 116, and the interconnect layer 126, which can be same as, or similar to, the corresponding components in the semiconductor device 100. The semiconductor device 100-1 can also include a substrate 154 and a peripheral circuit 156. The substrate 154 can be any suitable semiconductor substrate having any suitable semiconductor material, such as monocrystalline, polycrystalline or single crystalline semiconductor. For example, the substrate 154 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. The peripheral circuit 156 is between the stack 104 and the substrate 154 along the Z direction. The peripheral circuit 156 can be configured to control components (e.g., the conductive layers 104A and the channel structures 112) of the semiconductor device 100-1. In some implementations, the peripheral circuit 156 can be connected to bottom ends of the gate line structure 116 (e.g., an inner layer of a body portion of the gate line structure 116) and the channel structures 112 (e.g., a channel layer of each channel structure 112).

FIGS. 2A-2U illustrate an example process of fabricating a semiconductor device, such as the semiconductor device 100 or the semiconductor device 100-1 as illustrated in FIGS. 1A-IF. FIGS. 2A-2U show cross-sectional views (e.g., along a cut line at the same location of the cut line AA′ of FIG. 1A) of example semiconductor structures at various stages of the fabrication process.

As shown in FIG. 2A, a semiconductor structure 200a is formed. The semiconductor structure 200a includes a substrate 254 and a deck 204-1 of sacrificial layers 204C and isolating layers 204B. The sacrificial layers 204C and isolating layers 204B can alternate with each other along the vertical direction (e.g., the Z direction). The substrate 254 and each of the sacrificial layers 204C and isolating layers 204B can extend in the X-Y plane. The semiconductor structure 200a further includes a semiconductor layer 203 between the deck 204-1 and the substrate 254 along the Z direction. The semiconductor layer 203 can be made of a suitable semiconductor material (e.g., polysilicon). The semiconductor structure 200a can be formed by, for example, depositing the deck 204-1 of sacrificial layers 204C and isolating layers 204B over the semiconductor layer 203. The isolating layers 204B can include dielectric material, such as silicon oxide, silicon nitride, silicon oxynitride, or any combination thereof. In some implementations, the sacrificial layers 204C can include a dielectric material different from the dielectric material of the isolating layers 204B. For example, the isolating layers 204B can include silicon oxide, and the sacrificial layers 204C can include silicon nitride.

The semiconductor structure 200a includes gate line holes 217-1 arranged in a line extending along the X direction. The gate line holes 217-1 are spaced from one another along the line. The gate line holes 217-1 can include gate line holes in an array region (e.g., the array region 111 of FIG. 1A) of the semiconductor structure 200a and gate line holes in a connection region (e.g., the connection region 109 of FIG. 1A) of the semiconductor structure 200a. The semiconductor structure 200a further includes an array of channel holes 213-1 on both sides of the gate line holes 217-1 along the Y direction. The gate line holes 217-1 and the channel holes 213-1 extend through the deck 204-1 and the semiconductor layer 203 and into the substrate 254 along the Z direction. In some implementations, the gate line holes 217-1 and the channel holes 213-1 can be formed by a same etching process (e.g., a first etching process).

As shown in FIG. 2B, a semiconductor structure 200b is formed. The semiconductor structure 200b includes a deck 204-2 of sacrificial layers 204C and isolating layers 204B on top of the deck 204-1. The sacrificial layers 204C and isolating layers 204B in the deck 204-2 can alternate with each other along the vertical direction (e.g., the Z direction). The semiconductor structure 200b includes gate line holes 217-2 and channel holes 213-2 in the deck 204-2. The gate line holes 217-2 and the channel holes 213-2 can extend through the deck 204-2 along the Z direction. Each of the gate line holes 217-2 can be disposed on top of a corresponding gate line hole 217-1. Each of the channel holes 213-2 can be disposed on top of a corresponding channel hole 213-1. In other words, each gate line hole 217-2 is connected to and aligned with the corresponding gate line hole 217-1 along the Z direction, and each channel hole 213-2 is connected to and aligned with the corresponding channel hole 213-1 along the Z direction. The gate line holes 217-2 and the channel holes 213-2 can be formed by a same etching process (e.g., a second etching process).

As shown in FIG. 2C, a semiconductor structure 200c is formed by, for example, filling a sacrificial material (e.g., carbon) into the gate line holes 217-1 and 217-2 and the channel holes 213-1 and 213-2.

FIG. 2D shows a semiconductor structure 200d including a deck 204-3 of sacrificial layers 204C and isolating layers 204B. The sacrificial layers 204C and isolating layers 204B in the deck 204-3 can alternate with each other along the vertical direction (e.g., the Z direction). The semiconductor structure 200d can be formed, for example, by depositing the deck 204-3 of sacrificial layers 204C and isolating layers 204B on top of the deck 204-2.

As shown in FIG. 2E, a semiconductor structure 200e is formed. The semiconductor structure 200e includes gate line holes 217-3 and channel holes 213-3 in the deck 204-3. The gate line holes 217-3 and the channel holes 213-3 can extend through the deck 204-3 along the Z direction and expose the sacrificial material in the gate line holes 217-2 and the channel holes 213-2. Each of the gate line holes 217-3 can be disposed on top of a corresponding gate line hole 217-2. Each of the channel holes 213-3 can be disposed on top of a corresponding channel hole 213-2. In other words, each gate line hole 217-3 is aligned with the corresponding gate line hole 217-2 (and a corresponding gate line hole 217-1 under the gate line hole 217-2) along the Z direction, and each channel hole 213-3 is aligned with the corresponding channel hole 213-2 (and a corresponding channel hole 213-1 under the channel hole 213-2) along the Z direction. The gate line holes 217-3 and the channel holes 213-3 can be formed by a same etching process (e.g., a third etching process). The sacrificial material in the gate line holes 217-2 and 217-1 and the channel holes 213-2 and 213-1 can be removed, for example, by being burnt off. The aligned gate line holes 217-1, 217-2, and 217-3 can form a gate line hole 217. The aligned channel holes 213-1, 213-2, and 213-3 can form a channel hole 213. The decks 204-1, 204-2, and 204-3 can form a stack 204. It is understood that while in the semiconductor structure 200e the stack 204 includes three decks (e.g., decks 204-1, 204-2, and 204-3), and each of gate line hole 217 and channel hole 213 has three segments, the semiconductor structure 200e is merely an illustrative example. In practice, the stack 204 can include any suitable quantity of decks, and each deck can include any suitable quantity of alternating sacrificial layers and isolating layers.

FIG. 2F illustrates a semiconductor structure 200f including protection structures 205. The protection structures 205 can include poly oxidation and can be formed on bottoms of the gate line holes 217 and the channel holes 213 to protect the substrate 254. The protection structures 205 also can be formed on side walls of the semiconductor layer 203 that are exposed by the gate line holes 217 and the channel holes 213 to protect the semiconductor layer 203.

As shown in FIG. 2G, a semiconductor structure 200g is formed by, for example, filling a filler material (e.g., polysilicon) into the gate line holes 217 and the channel holes 213.

As shown in FIG. 2H, a semiconductor structure 200h is formed by depositing a sacrificial film 206 on top of the semiconductor structure 200g to cover the gate line holes 217 and the channel holes 213. The sacrificial film 206 can include a dielectric material such as silicon nitride.

FIG. 2I illustrates a semiconductor structure 200i including openings 207 formed in the sacrificial film 206 and on top of the channel holes 213 to expose the filler material in the channel holes 213.

FIG. 2J illustrates a semiconductor structure 200j formed by removing the filler material in the channel holes 213.

As shown in FIG. 2K, a semiconductor structure 200k is formed by depositing a high-K layer 212a, a memory film 212b, a channel layer 212c, and a core filler layer 212d into each of the channel holes 213. The memory film 212b can include a block layer, a charge trapping layer, and a tunneling layer. In some implementations, the channel layer 212c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof.

As shown in FIG. 2L, a semiconductor structure 200l including channel plugs 212e is formed. Each channel plug 212e includes polysilicon and is disposed above the core filler layer 212d. The channel plug 212e can be in contact with the channel layer 212c.

As shown in FIG. 2M, a semiconductor structure 200m is formed by removing excess material (e.g., a portion of each channel plug 212e, a portion of a dielectric material on top of the stack 204, a portion of the filler material in the gate line holes 217) on top of the semiconductor structure 200l by a planarization process, such as chemical mechanical polishing (CMP). The remaining structure in each channel hole 213 of the semiconductor structure 200m can be referred to as a respective channel structure 212, which includes the high-K layer 212a, the memory film 212b, the channel layer 212c, the core filler layer 212d, and the channel plug 212e.

As shown in FIG. 2N, a semiconductor structure 200n is formed by depositing a dielectric layer 208 (e.g., silicon oxide) on top of the semiconductor structure 200m to cover the channel structures 212 and the filler material in the gate line holes 217.

FIG. 2O illustrates a semiconductor structure 2000 including a gate line trench 210 extending along the X direction on top of the gate line holes 217. The gate line trench 210 can be formed by an etching process and can extend through the dielectric layer 208 along the Z direction to expose the filler material in the gate line holes 217. While FIG. 2O shows that a size of the gate line trench 210 along the Y direction is the same as a size (e.g., a maximum size) of the gate line holes 217 along the Y direction, this example is not intended to be limiting. In some other implementations, the size of the gate line trench 210 along the Y direction can be smaller or larger than the size of the gate line holes 217 along the Y direction.

As shown in FIG. 2P, a semiconductor structure 200p is formed by removing the filler material in the gate line holes 217.

FIG. 2Q illustrates a semiconductor structure 200q including a gate line space 215. The gate line space 215 can be formed by expanding the gate line trench 210 and the gate line holes 217 using an etching process. The etching process can remove dielectric materials (e.g., a portion of the dielectric layer 208 and the stack 204) exposed by the gate line trench 210 and the gate line holes 217. The expanded gate line holes 217 can be connected with one another along the X direction. In some implementations, a portion of the semiconductor layer 203 is exposed by the gate line space 215 because this etching process may not remove the semiconductor material in the semiconductor layer 203.

FIG. 2R illustrates a semiconductor structure 200r including an expanded gate line space 215. The gate line space 215 can be expanded by removing (e.g., by another etching process) the portion of the semiconductor layer 203 in the semiconductor structure 200q. The gate line space 215 in the semiconductor structure 200r includes a top portion 215a, a body portion 215b, and a bottom portion 215c. The top portion 215a is formed by the expanded gate line trench 210. The body portion 215b is formed by expanding a portion of each gate line hole 217 extending beyond the substrate 254. The bottom portion 215c is formed by a portion of each gate line hole 217 in the substrate 254. In some implementations, the etching process described with reference to FIG. 2Q is an isotropic wet etching process and creates rounded corners 219 adjacent to the top surface of the dielectric layer 208. As a result, the top portion 215a includes a first portion 215a-1 and a second portion 215a-2 arranged along the Z direction. The first portion 215a-1 is between two curved side surfaces of the rounded corners 219 along the Y direction. The second portion 215a-2 is between two flat surfaces under the rounded corners 219 along the Y direction. A cross section 244 of the first portion 215a-1 and a cross section 246 of the first portion 215a-1 are perpendicular to the Z direction. The cross section 244 is farther away from the substrate 254 than the cross section 246 along the Z direction. A size (e.g., a maximum size) of the cross section 244 along the Y direction is larger than a size (e.g., a maximum size) of the cross section 246 along the Y direction.

A cross section 248 of the second portion 215a-2 is perpendicular to the Z direction. A cross section 249 of the body portion 215b is perpendicular to the Z direction. The gate line trench 210 and the gate line holes 217 in the semiconductor structure 2000 can be expanded at similar speeds that are determined by an etching rate of the etching process described with reference to FIG. 2Q. Thus, a difference between a size (e.g., a maximum size) of the cross section 248 along the Y direction (referred to as a first expanded size) and a size (e.g., a maximum size) of the cross section 249 along the Y direction (referred to as a second expanded size) can be determined by the size (referred to as a first unexpanded size) of the gate line trench 210 in the semiconductor structure 2000 along the Y direction and the size (referred to as a second unexpanded size) of the gate line holes 217 in the semiconductor structure 2000 along the Y direction. For example, if the first unexpanded size is similar to, or equals the second unexpanded size (e.g., as shown in FIG. 2O), then the first expanded size can be similar to, or equal the second expanded size (e.g., as shown in FIG. 2R). In another example, if the first unexpanded size is larger than the second unexpanded size, then the first expanded size can be larger than the second expanded size. In another example, if the first unexpanded size is smaller than the second unexpanded size, then the first expanded size can be smaller than the second expanded size.

FIG. 2S shows a semiconductor structure 200s including conductive layers 204A. The sacrificial layers 204C in the stack 204 are replaced with the conductive layers 204A. The sacrificial layers 204C can be etched away, e.g., by filling an etchant into the gate line space 215. Then, the conductive layers 204A can be formed between the isolating layers 204B and in replace of the sacrificial layers 204C to form a new stack 204.

FIG. 2T shows a semiconductor structure 200t including a gate line structure 216. The gate line structure 216 can include an outer layer 234 formed by depositing a dielectric material (e.g., silicon oxide) on an inner surface of the gate line space 215, and an inner layer 236 formed by depositing a semiconductor material (e.g., polysilicon) into a space surrounded by the outer layer 234 in the gate line space 215. In some implementations, the gate line structure 216 can be a solid semiconductor structure absent of a dielectric material and can be formed by depositing a semiconductor material (e.g., polysilicon) into the gate line space 215. For example, the gate line structure 216 can be similar to the gate line structure 316 described with reference to FIG. 3N. The gate line structure 216 in the top portion 215a of the gate line space 215 can be referred to a top portion 238 of the gate line structure 216. The gate line structure 216 in the body portion 215b of the gate line space 215 can be referred to a body portion 240 of the gate line structure 216. The top portion 238 is farther away from a bottom end of the channel structure 212 than the channel plug 212e along the Z direction.

FIG. 2U shows a semiconductor structure 200u including a semiconductor layer 228. The substrate 254 of the semiconductor structure 200t is removed. In addition, a part of each channel structure 212 that was in the substrate 254 can be removed. For example, as shown in FIG. 2U, a part of the channel structure 212's memory film 212b that includes the ONO dielectrics (silicon Oxide-silicon Nitride-silicon Oxide) can be removed. Thus, the core filler layer 212d of the channel structure 212 can be exposed. The semiconductor layer 228 can be formed by depositing a suitable semiconductor material (e.g., polysilicon). The semiconductor layer 228 is connected to the gate line structure 216 and the channel structures 212.

The stack 204, the channel structures 212, the gate line structure 216, and the semiconductor layer 228 of the semiconductor structure 200u can be similar to, or same as, the corresponding components of the semiconductor device 100 described with reference to FIGS. 1A-1E. It is understood that, although not shown in FIG. 2U, the semiconductor device 100 can be formed from the semiconductor structure 200u using additional fabrication processes such as forming the interconnect layer 126 on top of the semiconductor structure 200u and bonding the semiconductor structure 200u to the semiconductor structure 102. It is also understood that the semiconductor device 100-1 of FIG. 1F can be formed using suitable variations of the fabrication processes described with reference to FIGS. 2A-2U.

FIGS. 3A-3N illustrate another example process of fabricating a semiconductor device, such as the semiconductor device 100 or the semiconductor device 100-1 as illustrated in FIGS. 1A-1F. FIGS. 3A-3N illustrate some variations of the fabrication processes described with reference to FIGS. 2A-2U. For example, a dielectric layer can be formed as a protection structure (e.g., as shown in FIG. 3A), which is different from the poly oxidation described with reference to FIG. 2F. In another example, a gate line structure (e.g., as shown in FIG. 3N) having a structure different from the one illustrated by FIG. 2T can be formed. FIGS. 3A-3N show cross-sectional views (e.g., along a cut line at the same location of the cut line AA′ of FIG. 1F) of example semiconductor structures at various stages of the fabrication process.

As shown in FIG. 3A, a semiconductor structure 300a is formed by depositing a dielectric layer 301 on an inner surface of each channel hole 213 and each gate line hole 217 of the semiconductor structure 200e of FIG. 2E. The dielectric layer 301 can also cover the top of the semiconductor structure 200e.

As shown in FIG. 3B, a semiconductor structure 300b is formed by, for example, filling a filler material (e.g., polysilicon) into the gate line holes 217 and the channel holes 213.

As shown in FIG. 3C, a semiconductor structure 300c is formed by depositing a sacrificial film 306 on top of the semiconductor structure 300b to cover the gate line holes 217 and the channel holes 213. The sacrificial film 306 can include a dielectric material such as silicon nitride.

FIG. 3D illustrates a semiconductor structure 300d including openings 307 formed in the sacrificial film 306 and on top of the channel holes 213 to expose the filler material in the channel holes 213.

FIG. 3E illustrates a semiconductor structure 300e formed by removing the filler material in the channel holes 213.

As shown in FIG. 3F, a semiconductor structure 300f is formed by depositing a high-K layer 312a, a memory film 312b, a channel layer 312c, and a core filler layer 312d into each of the channel holes 213. The memory film 312b can include a block layer, a charge trapping layer, and a tunneling layer. In some implementations, the channel layer 312c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof.

As shown in FIG. 3G, a semiconductor structure 300g including channel plugs 312e is formed. Each channel plug 312e includes polysilicon and is disposed above the core filler layer 312d. The channel plug 312e can be in contact with the channel layer 312c.

As shown in FIG. 3H, a semiconductor structure 300h is formed by removing excess material (e.g., a portion of each channel plug 312e, a portion of a dielectric material on top of the stack 204, a portion of the filler material in the gate line holes 217) on top of the semiconductor structure 300g by a planarization process (e.g., CMP). The remaining structure in each channel hole 213 of the semiconductor structure 300h can be referred to as a respective channel structure 312, which includes the high-K layer 312a, the memory film 312b, the channel layer 312c, the core filler layer 312d, and the channel plug 312c.

As shown in FIG. 3I, a semiconductor structure 300i is formed by depositing a dielectric layer 308 (e.g., silicon oxide) on top of the semiconductor structure 300h to cover the channel structures 312 and the filler material in the gate line holes 217.

FIG. 3J illustrates a semiconductor structure 300j including a gate line trench 310 extending along the X direction on top of the gate line holes 217. The gate line trench 310 can be formed by an etching process and can extend through the dielectric layer 308 along the Z direction to expose the filler material in the gate line holes 217. A size of the gate line trench 310 along the Y direction can be the same as, smaller than, or lager than a size (e.g., a maximum size) of the gate line holes 217 along the Y direction. Similar to what is described with reference to FIG. 2R, the size of the gate line trench 310 can affect a size of the top portion 315a of the gate line space 315 as shown below in FIG. 3M.

As shown in FIG. 3K, a semiconductor structure 300k is formed by removing the filler material in the gate line holes 217.

FIG. 3L illustrates a semiconductor structure 300l including a gate line space 315. The gate line space 315 can be formed by expanding the gate line trench 310 and the gate line holes 217 using an etching process. The etching process can remove dielectric materials (e.g., a portion of the dielectric layer 308 and the stack 204) exposed by the gate line trench 310 and the gate line holes 217. The expanded gate line holes 217 can be connected with one another along the X direction. In some implementations, a portion of the semiconductor layer 203 is exposed by the gate line space 315 because this etching process may not remove the semiconductor material in the semiconductor layer 203.

FIG. 3M illustrates a semiconductor structure 300m including an expanded gate line space 315. The gate line space 315 can be expanded by removing (e.g., by another etching process) the portion of the semiconductor layer 203 in the semiconductor structure 300l. The gate line space 315 in the semiconductor structure 300m includes a top portion 315a, a body portion 315b, and a bottom portion 315c. The top portion 315a is formed by the expanded gate line trench 310. The body portion 315b is formed by expanding a portion of each gate line hole 217 extending beyond the substrate 254. The bottom portion 215c is formed by a portion of each gate line hole 217 in the substrate 254. The gate line space 315 in the semiconductor structure 300m can be similar to, or same as, the gate line space 215 of FIG. 2R.

FIG. 3N shows a semiconductor structure 300n including a stack 304 and a gate line structure 316. The stack 304 can be formed from the stack 204 by replacing the sacrificial layers 204C with conductive layers 304A. The sacrificial layers 204C can be etched away, e.g., by filling an etchant into the gate line space 315. Then, the conductive layers 304A can be formed between the isolating layers 204B and in replace of the sacrificial layers 204C to form the new stack 304. A protection structures 305 (e.g., poly oxidation) can be formed on a bottom of the gate line space 315. The gate line structure 316 can be formed by depositing a semiconductor material (e.g., polysilicon) into the gate line space 315. In some implementations, the gate line structure 316 can have a structure different from the one illustrated by FIG. 3N. For example, the gate line structure 316 can include an outer layer made of a dielectric material and an inner surface made a semiconductor material (e.g., as described with reference to FIG. 2T).

The stack 304, the channel structures 312, and the gate line structure 316 of the semiconductor structure 300n can be similar to, or same as, the corresponding components of the semiconductor device 100 described with reference to FIGS. 1A-1E. Similar to what is described with reference to FIG. 2U, the semiconductor device 100 or 100-1 can be formed from the semiconductor structure 300n using additional fabrication processes and/or variations of the fabrication processes described with reference to FIGS. 3A-3N.

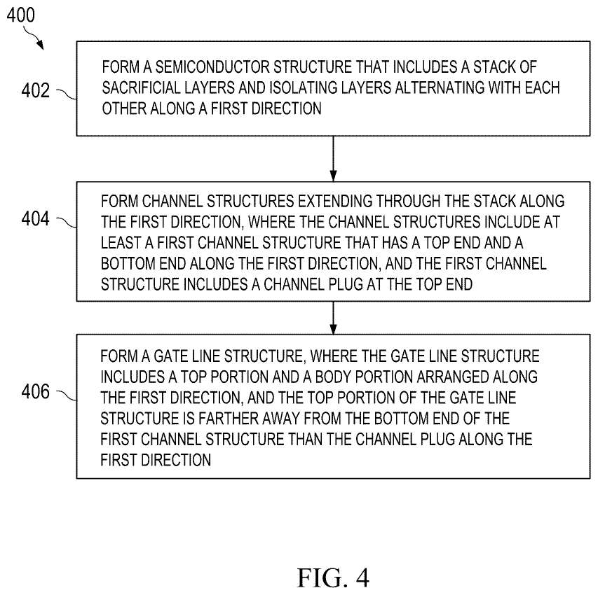

FIG. 4 illustrates a flow chart of an example process 400. The process 400 can be performed to form a semiconductor device (e.g., the semiconductor device 100 or 100-1 illustrated by FIGS. 1A-1F). The process 400 can be described in view of FIGS. 2A-2U and 3A-3N. The process 400 can include one or more steps of the fabrication process of forming the semiconductor structures in FIGS. 2A-2U and 3A-3N. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a semiconductor structure (e.g., the semiconductor structure 200g of FIG. 2G) is formed. The semiconductor structure includes a stack (e.g., the stack 204) of sacrificial layers (e.g., sacrificial layers 204C) and isolating layers (e.g., isolating layers 204B) alternating with each other along a first direction (e.g., the Z direction).

At operation 404, channel structures (e.g., channel structures 212 of FIG. 2M) extending through the stack along the first direction are formed. The channel structures include at least a first channel structure that has a top end and a bottom end along the first direction. The first channel structure includes a channel plug (e.g., the channel plug 212c) at the top end.

At operation 406, a gate line structure (e.g., the gate line structure 216 of FIG. 2T) is formed. The gate line structure includes a top portion (e.g., the top portion 238) and a body portion (e.g., the body portion 240) arranged along the first direction. The top portion of the gate line structure is farther away from the bottom end of the first channel structure than the channel plug along the first direction.

In some implementations, the process 400 further includes depositing a dielectric layer (e.g., the dielectric layer 208 of FIG. 2N) on top of the stack to cover the channel structures and gate line holes (e.g., the gate line holes 217). The gate line holes are spaced from one another along a second direction (e.g., the X direction) perpendicular to the first direction and are filled with a filler material.

In some implementations, the process 400 further includes forming a trench (e.g., the gate line trench 210 of FIG. 2O) in the dielectric layer to expose the filler material of the gate line holes.

In some implementations, the process 400 further includes removing the filler material from the gate line holes (e.g., as described with reference to FIG. 2P).

In some implementations, the process 400 further includes forming a gate line space (e.g., the gate line space 215 of FIG. 2R) by expanding the trench and the gate line holes (e.g., as described with reference to FIGS. 2Q and 2R). The expanded gate line holes are connected.

In some implementations, the gate line space includes a top portion (e.g., the top portion 215a of FIG. 2R) formed by the expanded trench and a body portion (e.g., the body portion 215b of FIG. 2R) formed by the expanded gate line holes. A first cross section (e.g., cross section 244) of the top portion and a second cross section (e.g., cross section 246) of the top portion are perpendicular to the first direction. The first cross section of the top portion is farther away from the body portion than the second cross section along the first direction. A size of the first cross section along a third direction (e.g., the Y direction) perpendicular to the first direction and the second direction is larger than a size of the second cross section along the third direction.

In some implementations, a third cross section (e.g., cross section 248 of FIG. 2R) of the top portion is adjacent to the body portion and perpendicular to the first direction. A size of the third cross section along the third direction is smaller than a size (e.g., the size of the cross section 249) of the body portion along the third direction.

In some implementations, the process 400 further includes forming the gate line holes and channel holes extending through the stack along the first direction (e.g., as described with reference to FIG. 2E). The gate line holes include gate line holes in an array region of the semiconductor structure and gate line holes in a connection region of the semiconductor structure. The channel structures are formed in the channel holes (e.g., as described with reference to FIGS. 2K, 2L, and 2M).

In some implementations, the process 400 further includes forming the channel structures in the channel holes (e.g., as described with reference to FIGS. 2K, 2L, and 2M) prior to forming the gate line space by expanding the trench and the gate line holes (e.g., as described with reference to FIGS. 2Q and 2R). The channel structures are formed by depositing a high-K layer (e.g., the high-K layer 212a of FIG. 2K), a block layer (e.g., the block layer of the memory film 212b), a charge trapping layer (e.g., the charge trapping layer of the memory film 212b), a tunneling layer (e.g., the tunneling layer of the memory film 212b), a channel layer (e.g., the channel layer 212c), and a core filler layer (e.g., the core filler layer 212d) into each of the channel holes.

In some implementations, forming the semiconductor structure includes depositing multiple decks (e.g., decks 2041, 204-2, and 204-3 of FIG. 2E) of sacrificial layers and isolating layers and forming the gate line holes and the channel holes in each of the multiple decks by a respective etching process (e.g., as described with reference to FIGS. 2A-2E). The stack (e.g., the stack 204) includes the multiple decks.

In some implementations, the process 400 further includes removing the sacrificial layers in the stack by filling an etchant into the gate line space and forming conductive layers (e.g., conductive layers 204A) between the isolating layers in the stack (e.g., as described with reference to FIG. 2S).

In some implementations, forming the gate line structure includes: forming an outer layer (e.g., the outer layer 234 of FIG. 2T) of the gate line structure by depositing a dielectric material on an inner surface of the gate line space; and forming an inner layer (e.g., the inner layer 236 of FIG. 2T) of the gate line structure by depositing a semiconductor material into the gate line space.

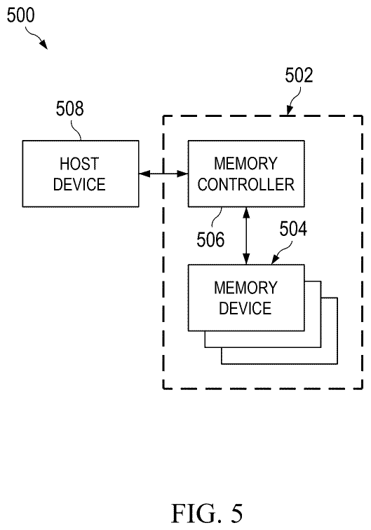

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a NAND Flash memory) as shown in FIGS. 1A-IF. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +−0.10%, +−0.20%, or +−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a semiconductor structure comprising a stack of conductive layers and isolating layers alternating with each other along a first direction;
channel structures extending through the stack along the first direction, wherein the channel structures comprise at least a first channel structure that has a top end and a bottom end along the first direction, and the first channel structure comprises a channel plug at the top end; and
a gate line structure extending through the stack along the first direction, wherein the gate line structure comprises a top portion and a body portion arranged along the first direction, and the top portion of the gate line structure is farther away from the bottom end of the first channel structure than the channel plug along the first direction.

2. The semiconductor device of claim 1, wherein a side surface of the top portion comprises a curved surface and a flat surface, and the flat surface is between the curved surface and the body portion along the first direction, and
wherein a side surface of the body portion comprises a series of curved surfaces arranged along a second direction perpendicular to the first direction.

3. The semiconductor device of claim 2, wherein the top portion comprises a first portion and a second portion arranged along the first direction, the second portion is connected to the body portion, the first portion is farther away from the body portion than the second portion along the first direction, and
wherein a size of the first portion along a third direction perpendicular to the first direction and the second direction is larger than or equal to a size of the second portion along the third direction.

4. The semiconductor device of claim 3, wherein the size of the second portion of the top portion along the third direction is smaller than a size of the body portion along the third direction.

5. The semiconductor device of claim 1, wherein the top portion of the gate line structure extends beyond the channel plug along the first direction by a length in a range between 20 nanometers (nm) and 300 nm.

6. The semiconductor device of claim 1, wherein the gate line structure comprises an outer layer and an inner layer surrounded by the outer layer, the outer layer comprises a dielectric material, and the inner layer comprises a semiconductor material.

7. The semiconductor device of claim 1, wherein the semiconductor structure comprises a semiconductor layer connected to the body portion of the gate line structure and the bottom end of the first channel structure.

8. The semiconductor device of claim 7, wherein the semiconductor structure is a first semiconductor structure, the semiconductor device further comprises a second semiconductor structure comprising a peripheral circuit configured to control the channel structures, and the first semiconductor structure is connected to the second semiconductor structure along the first direction.

9. The semiconductor device of claim 1, further comprising a substrate and a peripheral circuit configured to control the channel structures, the peripheral circuit is between the stack and the substrate along the first direction, and the peripheral circuit is connected to the body portion of the gate line structure and the bottom end of the first channel structure.

10. A method, comprising:
forming a semiconductor structure that comprises a stack of sacrificial layers and isolating layers alternating with each other along a first direction;
forming channel structures extending through the stack along the first direction, wherein the channel structures comprise at least a first channel structure that has a top end and a bottom end along the first direction, and the first channel structure comprises a channel plug at the top end; and
forming a gate line structure, wherein the gate line structure comprises a top portion and a body portion arranged along the first direction, and the top portion of the gate line structure is farther away from the bottom end of the first channel structure than the channel plug along the first direction.

11. The method of claim 10, further comprising:
depositing a dielectric layer on top of the stack to cover the channel structures and gate line holes, the gate line holes being spaced from one another along a second direction perpendicular to the first direction and filled with a filler material;
forming a trench in the dielectric layer to expose the filler material of the gate line holes;
removing the filler material from the gate line holes; and
forming a gate line space by expanding the trench and the gate line holes, wherein the expanded gate line holes are connected.

12. The method of claim 11, wherein the gate line space comprises a top portion formed by the expanded trench and a body portion formed by the expanded gate line holes, a first cross section of the top portion and a second cross section of the top portion are perpendicular to the first direction, the first cross section of the top portion is farther away from the body portion than the second cross section along the first direction, and a size of the first cross section along a third direction perpendicular to the first direction and the second direction is larger than a size of the second cross section along the third direction.

13. The method of claim 12, wherein a third cross section of the top portion is adjacent to the body portion and perpendicular to the first direction, and a size of the third cross section along the third direction is smaller than a size of the body portion along the third direction.

14. The method of claim 11, further comprising:
forming the gate line holes and channel holes extending through the stack along the first direction, wherein the gate line holes comprise gate line holes in an array region of the semiconductor structure and gate line holes in a connection region of the semiconductor structure, and the channel structures are formed in the channel holes.

15. The method of claim 14, wherein forming the semiconductor structure comprises:
depositing multiple decks of sacrificial layers and isolating layers, wherein the stack comprises the multiple decks; and
forming the gate line holes and the channel holes in each of the multiple decks by a respective etching process.

16. The method of claim 11, further comprising:
removing the sacrificial layers in the stack by filling an etchant into the gate line space; and
forming conductive layers between the isolating layers in the stack.

17. The method of claim 16, wherein forming the gate line structure comprises:
forming an outer layer of the gate line structure by depositing a dielectric material on an inner surface of the gate line space; and
forming an inner layer of the gate line structure by depositing a semiconductor material into the gate line space.

18. A memory system, comprising:
a memory device; and
a memory controller coupled to the memory device and configured to control the memory device,
wherein the memory device comprises:
a semiconductor structure comprising a stack of conductive layers and isolating layers alternating with each other along a first direction;
channel structures extending through the stack along the first direction, wherein the channel structures comprise at least a first channel structure that has a top end and a bottom end, and the first channel structure comprises a channel plug in the top end; and
a gate line structure extending through the stack along the first direction, wherein the gate line structure comprises a top portion and a body portion arranged along the first direction, and the top portion is farther away from the bottom end of the first channel structure than the channel plug along the first direction.

19. The memory system of claim 18, wherein a side surface of the top portion comprises a curved surface and a flat surface, the flat surface is between the curved surface and the body portion along the first direction, and a side surface of the body portion comprises a series of curved surfaces arranged along a second direction perpendicular to the first direction.

20. The memory system of claim 18, wherein the top portion of the gate line structure extends beyond the channel plug along the first direction by a length in a range between 20 nanometers (nm) and 300 nm.
